(19) United States
(12) Patent Application Publication
(10) Pub. No.: US 2026/0143687 A1
(43) Pub. Date: May 21, 2026

(54) SEMICONDUCTOR DEVICES

(71) Applicant: Samsung Electronics Co., Ltd., Suwon-si (KR)

(72) Inventors: Eunsuk Jang, Suwon-si (KR); Jinwoo Han, Suwon-si (KR); Woochul Kim, Suwon-si (KR); Hyebin Kim, Suwon-si (KR); Jihoon Choi, Suwon-si (KR); Seunguk Han, Suwon-si (KR)

(21) Appl. No.: 19/391,262

(22) Filed: Nov. 17, 2025

(30) Foreign Application Priority Data
Nov. 18, 2024 (KR) 10-2024-0164527

(51) Int. Cl. H10B 12/00; H10D 1/68; H10D 62/17

(52) U.S. Cl. CPC H10B 12/482; H10D 1/714; H10D 62/235; H10B 12/03; H10B 12/05

(57) ABSTRACT

The semiconductor device includes a bit line on a substrate, the bit line including a first conductive pattern extending in a vertical direction and including a metal, a second conductive pattern at least partially covering opposite sidewalls of the first conductive pattern in a first horizontal direction and including a silicide, and a third conductive pattern at least partially covering opposite outer opposite sidewalls in the first horizontal direction of the second conductive pattern and including a first semiconductor material doped with first impurities; channels including a second semiconductor material and on each outer opposite sidewalls in the first horizontal direction of the third conductive pattern; gate electrodes each extending in a second horizontal direction, and at least partially surrounding first end portions in the first horizontal direction of the channels; and capacitors on opposite sidewalls of second end portions in the first horizontal direction of the channels.

### CROSS-REFERENCE TO RELATED APPLICATION

This application claims priority under 35 U.S.C. § 119 to Korean Patent Application No. 10-2024-0164527, filed on Nov. 18, 2024 in the Korean Intellectual Property Office (KIPO), the disclosure of which is incorporated by reference herein in its entirety.

### TECHNICAL FIELD

Example embodiments of the inventive concept relate to a semiconductor device. More particularly, example embodiments of the inventive concept relate to a three-dimensional (3D) memory device.

### DISCUSSION OF RELATED ART

A DRAM device includes word lines, bit lines, channels and capacitors. In order to increase the integration degree of the DRAM device, the word lines, the bit lines, the channels and the capacitors should be efficiently arranged.

### SUMMARY

Example embodiments of the inventive concept provide a semiconductor device having enhanced electrical characteristics.

According to example embodiments of the inventive concept, there is provided a semiconductor device. The semiconductor device may include a substrate; a bit line on the substrate, the bit line including a first conductive pattern, a second conductive pattern, and a third conductive pattern; channels extending in a first horizontal direction that is parallel to an upper surface of the substrate; gate electrodes extending in a second horizontal direction that is parallel to the upper surface of the substrate and crosses the first horizontal direction; and capacitors on the substrate. The first conductive pattern extends in a vertical direction, the first conductive pattern includes a metal, and the first conductive pattern includes first opposite sidewalls facing away from each other in the first horizontal direction. The second conductive pattern at least partially covers the first opposite sidewalls, the second conductive pattern includes a silicide, and the second conductive pattern includes second opposite sidewalls facing away from each other in the first horizontal direction. The third conductive pattern at least partially covers the second opposite sidewalls, the third conductive pattern includes a first semiconductor material doped with first impurities, and the third conductive pattern includes third opposite sidewalls facing away from each other in the first horizontal direction. The channels include a second semiconductor material, the channels are disposed spaced apart from each other along the vertical direction, each of the channels is formed on the third opposite sidewalls of a corresponding one of third conductive pattern, and each of the channels includes a first end portion and a second end portion that face away from each other in the first horizontal direction. The gate electrodes extend in the second horizontal direction, and each of the gate electrodes at least partially surrounds the first end portion of a corresponding one of the channels, and each of the capacitors is disposed on the second end portion of a corresponding one of the channels.

According to example embodiments of the inventive concept, there is provided a semiconductor device. The semiconductor device may include a substrate; a bit line on the substrate, the bit line including a filling pattern, a first conductive pattern, and a second conductive pattern; a channel extending in a first horizontal direction that is parallel to an upper surface of the substrate; gate electrodes extending in a second horizontal direction that is parallel to the upper surface of the substrate and crosses the first horizontal direction; a gate electrode extending in the second horizontal direction; and capacitors on the substrate. The bit line includes a first sidewall facing along the first horizontal direction, the filling pattern extends in a vertical direction, the filling pattern includes second opposite sidewalls facing away from each other in the first horizontal direction, the first conductive pattern at least partially covering the second opposite sidewalls of the filling pattern, the first conductive pattern includes a silicide, the first conductive pattern includes third opposite sidewalls facing away from each other in the first horizontal direction, the second conductive pattern at least partially covers the third opposite sidewalls, the second conductive pattern includes a first semiconductor material doped with first impurities, the channel extends in the first horizontal direction from the first sidewall the bit line, the channel includes first and second end portions facing away from each other in the first horizontal direction, the first end portion includes fourth opposite sidewalls facing away from each other in the second horizontal direction, the second horizontal direction is parallel to the upper surface of the substrate and crosses the first horizontal direction, the gate electrode at least partially covers upper and lower surfaces and the fourth opposite sidewalls of the first end portion of the channel, the capacitor at least partially covers the second end portion of the channel, and a portion of the first end portion of the channel adjacent to the second conductive pattern includes the first impurities.

According to example embodiments of the inventive concept, there is provided a semiconductor device. The semiconductor device may include a substrate; bit lines on the substrate and spaced apart from each other in a first horizontal direction parallel to an upper surface of the substrate, each of the bit lines including a filling pattern, a first conductive pattern, a second conductive pattern and a third conductive pattern; isolation patterns between neighboring ones of the bit lines in the first horizontal direction, the isolation patterns extending in a vertical direction; channels extending in a second horizontal direction that is parallel to the upper surface of the substrate and crosses the first horizontal direction; gate electrodes extending in the first horizontal direction; and capacitors on the substrate. The filling patterns extend in the vertical direction, each of the filling patterns includes first opposite sidewalls facing away from each other in the second horizontal direction, each of the filling patterns further includes second opposite sidewalls facing away from each other in the first horizontal direction, each of the first conductive patterns covers the first opposite sidewalls of a corresponding one of the filling patterns, the first conductive patterns include a metal, each of the first conductive patterns includes third opposite sidewalls facing away from each other in the second horizontal direction, each of the first conductive patterns further includes fourth opposite sidewalls facing away from each other in the first horizontal direction, each of the second conductive patterns at least partially covers the third opposite sidewalls of a corresponding one of the first conductive patterns, each of the second conductive patterns includes a silicide, each of the second conductive patterns includes fifth opposite sidewalls facing away from each other in the second horizontal direction, each of the second conductive patterns further includes sixth opposite sidewalls facing away from each other in the second horizontal direction, each of the third conductive patterns at least partially covers the fifth opposite sidewalls of a corresponding one of the second conductive patterns, the third conductive patterns include a semiconductor material doped with first impurities, each of the third conductive patterns includes seventh opposite sidewalls facing away from each other in the second horizontal direction, and each of the third conductive patterns further includes eighth opposite sidewalls facing away from each other in the second horizontal direction. Each of the isolation patterns covers the second opposite sidewalls of a corresponding one of the filling patterns, the third opposite sidewalls of a corresponding one of the first conductive patterns, the sixth opposite sidewalls of a corresponding one of the second conductive patterns, and the eighth opposite sidewalls of a corresponding one of the third conductive patterns, Each of the channels is disposed on the seventh opposite sidewalls of a corresponding one of the third conductive patterns, each of the channels extends in the second horizontal direction, the channels are spaced apart from each other along the vertical direction, each of the gate electrodes at least partially surrounds a first end portion in the second horizontal direction of a corresponding one of the channels, and each of the capacitors at least partially covers a second end portion in the second horizontal direction of a corresponding one of the channels.

The semiconductor device in accordance with example embodiments may include ohmic contacts disposed between the channels and the bit line structure. Impurity concentration of the ohmic contacts may be uniformly formed along the vertical direction.

Additionally, the bit line structure may include sequentially stacked first, second, and third conductive patterns. The second conductive pattern may include a silicide, and thus contact resistance between the first conductive pattern including a semiconductor material and the third conductive pattern including a metal or a metal nitride may be minimized.

### BRIEF DESCRIPTION OF THE DRAWINGS

FIGS. 1 to 5 are a perspective view, a horizontal cross-sectional view, and vertical cross-sectional views illustrating a semiconductor device in accordance with example embodiments.

FIGS. 6 to 31 are vertical cross-sectional views and horizontal cross-sectional views illustrating a method of manufacturing a semiconductor device in accordance with example embodiments.

FIGS. 32 to 46 are perspective views, horizontal cross-sectional views, and vertical cross-sectional views illustrating a semiconductor device in accordance with example embodiments.

### DETAILED DESCRIPTION OF THE EMBODIMENTS

The above and other aspects and features of the semiconductor devices and the methods of manufacturing the same in accordance with example embodiments will become readily understood from detailed descriptions that follow, with reference to the accompanying drawings. It will be understood that, although ordinal numbers such as “first,” “second,” and/or “third” may be used herein as labels to distinguish between various elements and/or processes and will be understood not be limited by these terms. In addition, a term that is referenced with a particular ordinal number (e.g., “first” in a particular claim) may be referenced elsewhere with a different ordinal number (e.g., “second” in the specification or another claim).

First and second directions D1 and D2 may be reference directions that are substantially parallel to an upper surface of the substrate, which intersect each other. Third direction D3 may refer to a direction perpendicular to the first and second directions D1 and D2. In example embodiments, the first and second directions D1 and D2 may be substantially perpendicular to each other. Each of the first to third directions D1, D2 and D3 may include not only a direction shown in the drawings but also a direction opposite thereto. For ease of description, first and second direction D1 and D1 may be considered as horizontal directions and third direction may be considered a vertical direction. Similarly, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Items described in the singular herein may be provided in plural, as can be seen, for example, in the drawings. Thus, the description of a single item that is provided in plural should be understood to be applicable to the remaining plurality of items unless context indicates otherwise.

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

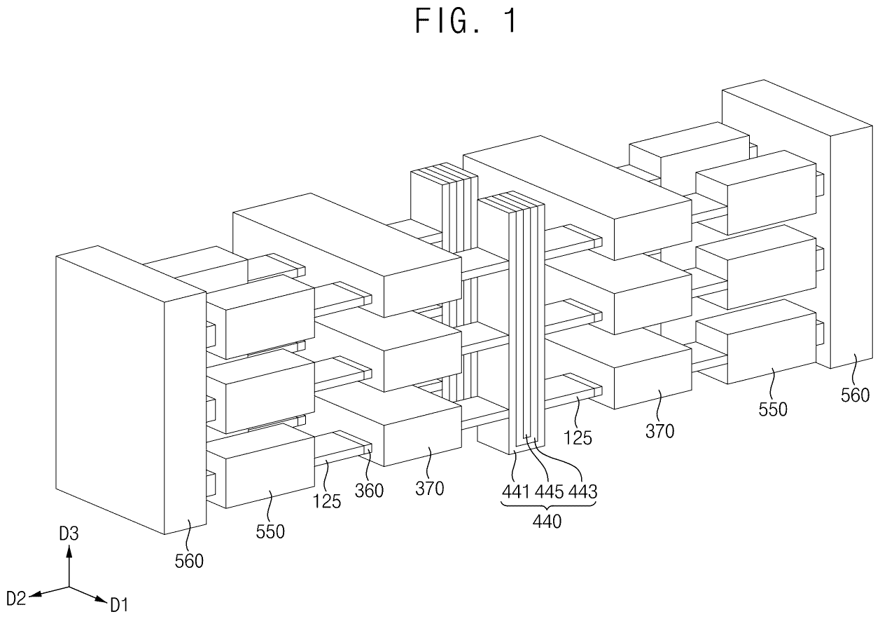

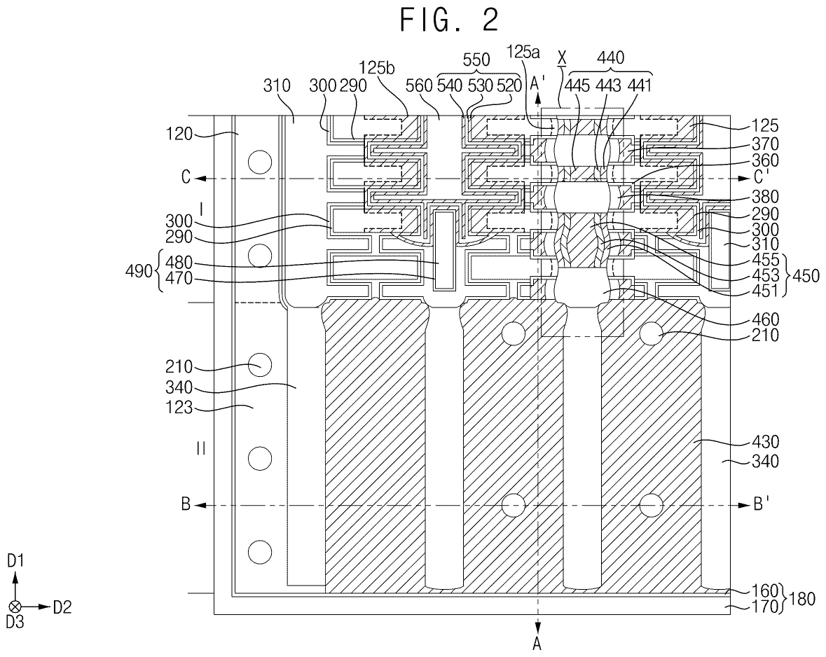

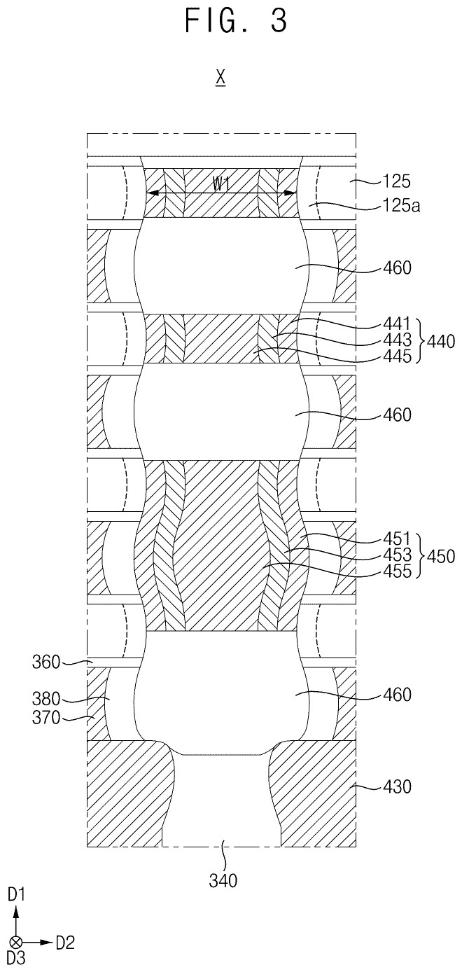

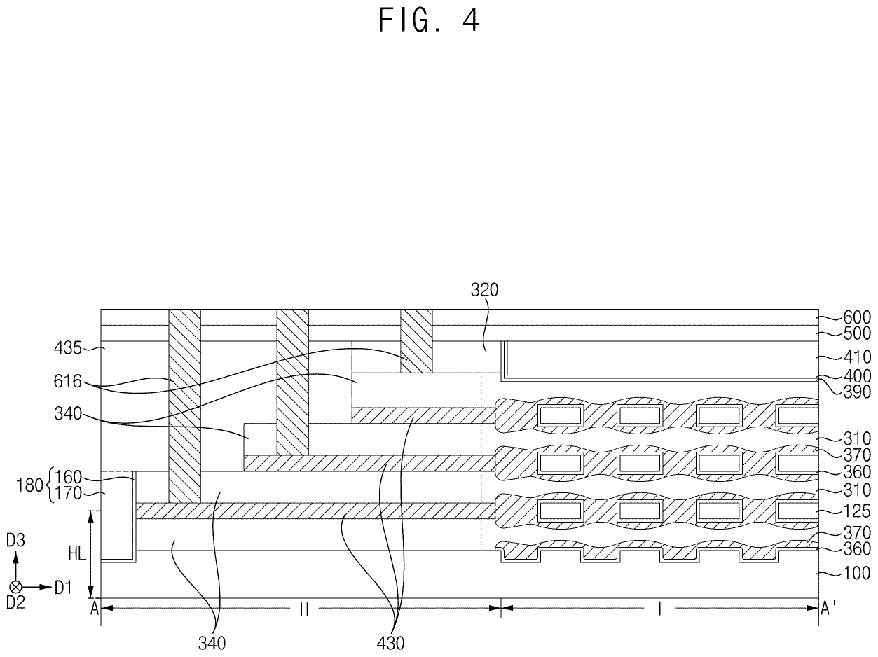

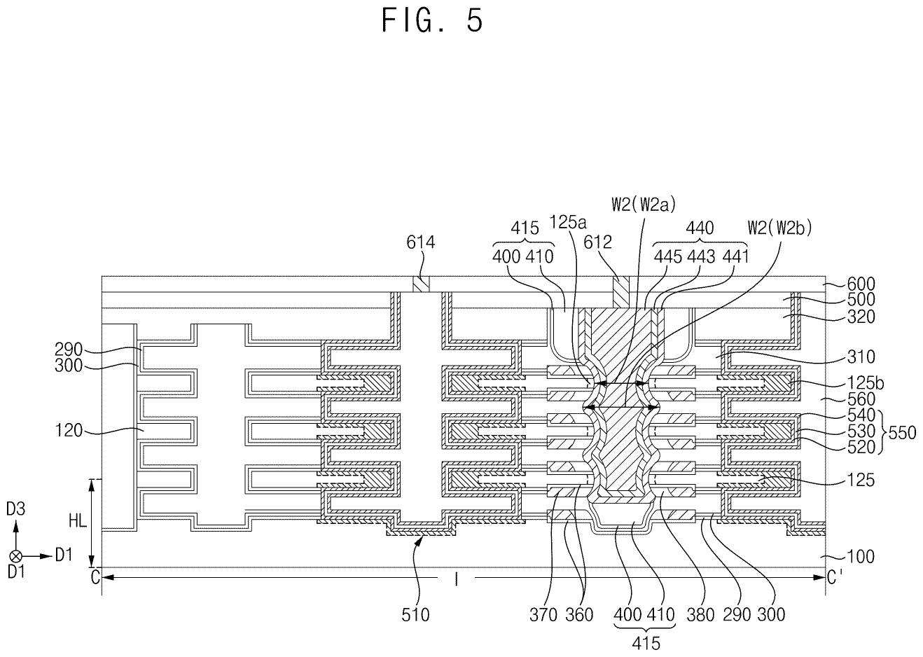

FIGS. 1 to 5 are a perspective view, a horizontal cross-sectional view, and vertical cross-sectional views illustrating a semiconductor device in accordance with example embodiments. Particularly, FIG. 1 is a perspective view of FIGS. 2 to 5 and is a schematic diagram showing main elements of the semiconductor device. FIG. 2 is a horizontal cross-sectional view at a height (vertical level) HL of FIGS. 4 and 5. FIG. 3 is an enlarged cross-sectional view of a region X of FIG. 2. FIGS. 4 and 5 are vertical cross-sectional views taken along lines A-A′ and C-C′ of FIG. 2, respectively.

Referring to FIGS. 1 to 5, the semiconductor device may include a memory cell region in which memory cells are formed and a peripheral circuit region in which circuits for applying electrical signals to the memory cells are formed. The memory cell region may include memory cell block regions each of which may include memory cells. The memory cell block regions may be arranged in each of the first and second directions D1 and D2, and may be separated from each other by a first division structure (or isolation pattern) 180.

The first division structure 180 may contact an upper surface of the memory cell region of the substrate 100, and may have a lattice shape (e.g., a grid structure) in a plan view (a top down view). For example, with respect to a plan view, the first division structure 180 may surround each of the memory cell block regions (e.g., each of the memory cell block regions may be formed in a corresponding cell of the lattice formed by the first division structure 180). In an example embodiment, the first division structure 180 may include a first division pattern 160 and a second division pattern 170 covering a sidewall and a lower surface of the first division pattern 160. The first division pattern 160 may include an insulating nitride, e.g., silicon nitride, and the second division pattern 170 may include an oxide, e.g., silicon oxide. Throughout the spec, division structures (including the first and second division pattern 170) may be isolation patterns or isolation structure).

Each of the memory cell block regions may include first and second regions I and II. The first region I may be a memory cell array region in which a memory cell array of the memory cells is formed, and the second region II may be a pad region or an extension region in which contact plugs for transferring electrical signals to the memory cell array and conductive pads contacting the contact plugs are formed.

In example embodiments, the second region II may be disposed at one side or two second regions II may be formed on opposite sides in the first direction D1 of the first region I. FIG. 2 shows a portion of the memory cell block region including a portion of each of the first and second regions I and II.

The semiconductor device may include channels 125, gate structures, bit line structures 440, capacitor structures, conductive pads 430, and first to third contact plugs 612, 614 and 616.

Additionally, the semiconductor device may include a dummy bit line structure 450, blocking structures 490, a first division structure 180, a third division structure, a fourth division structure 415, support patterns 210, semiconductor layers 120, semiconductor patterns 123, a second mask 320, an eighth division pattern 340, eleventh division patterns 460, second and third insulating interlayers 435 and 600, and a capping layer 500 on the substrate 100.

As used herein, the term “dummy” is used to refer to a component that has the same as or similar structure and shape as other components but does not have a substantial function (e.g., to convey information). The “dummy” element may only exist as a pattern in the device. In some instances, a “dummy” element may be electrically floated, or may be connected to various voltage sources but otherwise not provide the same functionality of the non-dummy element it represents. For example, a dummy bit line may not connect to memory cells, or may have dummy memory cells connected to it (e.g., no data is read from the dummy memory cells and/or output from the dummy memory cells to an external device).

The substrate 100 may include a semiconductor material, e.g., silicon, germanium, silicon-germanium, etc., or a III-V group compound semiconductor, such as GaP, GaAs, GaSb, etc. In an example embodiment, the substrate 100 may be a silicon-on-insulator (SOI) substrate or a germanium-on-insulator (GOI) substrate.

The channels 125 may extend in the second direction D2 on the first region I of the substrate 100. The channels 125 may be spaced apart from each other along the third direction D3, and may be spaced apart from each other along the first and second directions D1 and D2 at substantially the same height (vertical level) from the upper surface of the substrate 100. Each of channel columns may include a group of the channels 125 spaced apart from each other along the first direction D1 at substantially the same height, and the channel columns may be spaced apart from each other along the second and third directions D2 and D3. Each of channel arrays may include a group of the channel columns spaced apart from each other along the second direction D2 at substantially the same height, and the channel arrays may be spaced apart from each other along the third direction D3.

The semiconductor layers 120 may extend in the first direction D1 at each of opposite sides in the second direction D2 on the first region I of the substrate 100. In example embodiments, the semiconductor layers 120 and the channels 125 may be disposed at substantially the same height from the upper surface of the substrate 100.

The semiconductor patterns 123 may extend in the first direction D1 at each of opposite sides in the second direction D2 on the second region II of the substrate 100. The semiconductor patterns 123 may contact and be connected to the semiconductor layers 120.

The channels 125, the semiconductor layers 120 and the semiconductor patterns 123 may include substantially the same material, e.g., a first semiconductor material such as silicon.

The gate structures may extend in the first direction D1 and may be spaced apart from each other along the second and third directions D2 and D3. In example embodiments, each of the gate structures may extend in the first direction D1 while surrounding upper and lower surfaces and opposite sidewalls in the first direction D1 of first end portions in the second direction D2 of the channels 125 included in a corresponding channel column on the first region I of the substrate 100. Each of the gate structures may serve as a word line of the semiconductor device.

The gate structures may include gate electrodes 370, gate insulation patterns 360, and gate masks 380. In example embodiments, each of the gate structures may include a group of the gate insulation patterns 360 covering surfaces of the first end portions of the channels 125 included in the corresponding channel column, and a gate electrode 370 and a gate mask 380 surrounding the group of the gate insulation patterns 360.

The gate insulation patterns 360 may cover lower and upper surfaces and opposite sidewalls in the first direction D1 of the first end portions of the channels 125. Each gate insulation pattern 360 may take the form of a tube having a corresponding one of the channels formed therein (e.g., a channel 125 may extend through the tube-shaped gate insulating pattern 360. The gate insulation patterns 360 may include an oxide, e.g., silicon oxide.

The gate electrode 370 may extend in the first direction D1, and may cover lower and upper surfaces and opposite sidewalls in the first direction D1 of portions of the gate insulation patterns 360 arranged in the first direction D1. The gate electrodes 370 may include a conductive material, e.g., a metal, a metal nitride, silicide, etc.

The gate mask 380 and may contact a sidewall in the second direction D2 of the gate electrode 370, may extend in the first direction D1, and may cover lower and upper surfaces and opposite sidewalls in the first direction D1 of portions of the gate insulation patterns 360 arranged in the first direction D1. The gate masks 380 may include an insulating nitride, e.g., silicon nitride.

The conductive pads 430 may extend in the first direction D1 on the second region II of the substrate 100, and may be spaced apart from each other in the second direction D2. In example embodiments, at least a portion of a conductive pad 430 may be disposed at substantially the same height as the gate electrode 370, and may contact a sidewall in the first direction D1 of the gate electrode 370 to be electrically connected thereto. In example embodiments, the conductive pads 430 may overlap the gate structures and the channels 125 in the first direction D1.

In example embodiments, the conductive pads 430 may be spaced apart from each other in the third direction D3, and lengths in the first direction D1 of the conductive pads 430 may decrease from a lowermost one to an uppermost one thereof in a stepwise manner. Thus, the conductive pads 430 disposed in the third direction D3 may form a staircase structure.

The conductive pads 430 may include a conductive material, e.g., a metal, a metal nitride, a silicide, doped polysilicon, etc.

In example embodiments, the third division structure may include first and second insulation patterns 290 and 300 and a seventh division pattern 310.

The third division structure may fill spaces between the gate structures, the channels 125 and the semiconductor layers 120 that are stacked in the third direction D3, between the upper surface of the substrate 100 and each of a lowermost gate structure, a lowermost channel 125 and a lowermost semiconductor layer 120, and between the second mask 320 and each of an uppermost gate structure, an uppermost channel 125 and an uppermost semiconductor layer 120. Additionally, the third division structure may fill spaces between the channels neighboring in the second direction D2, and between the channels 125 and the semiconductors layers 120 neighboring in the second direction D2.

The first and second insulation patterns 290 and 300 may be sequentially stacked on surfaces of the channels 125, and the seventh division pattern 310 may be disposed on the second insulation pattern 300 and fill other portions of the spaces.

The first insulation pattern 290 and the seventh division pattern 310 may include an oxide, e.g., silicon oxide, and the second insulation pattern 300 may include an insulating nitride, e.g., silicon nitride.

The eighth division pattern 340 may include vertical extension portions and horizontal extension portions. The horizontal portions of the eighth division pattern 340 may be disposed on the second region II of the substrate 100, and may fill spaces between the conductive pads 430 and the semiconductor patterns 123 that are stacked in the third direction D3, between the upper surface of the substrate 100 and each of a lowermost conductive pad 430 and a lowermost semiconductor pattern 123, and between the second mask 320 and each of an uppermost conductive pad 430 and an uppermost semiconductor pattern 123. Additionally, the vertical extension portions of the eighth division pattern 340 may extend in the third direction D3 to contact the upper surface of the substrate 100, and may extend in the first direction D1 between the conductive pads 430 neighboring in the second direction D2 to fill spaces therebetween.

In example embodiments, lengths in the first direction D1 of the horizontal portions of the eighth division pattern 340 disposed in the third direction D3 may decrease from a lowermost one to an uppermost one in a stepwise manner, and thus a stack structure including the horizontal portions of the eighth division pattern 340 may be a staircase structure. In example embodiments, a horizontal portion of the eighth division pattern 340 on a corresponding one of the conductive pads 430 may collectively form one step layer, and a sidewall in the first direction D1 of the horizontal portion of the eighth division pattern 340 may be aligned with a sidewall in the first direction D1 of the corresponding one of the conductive pads 430 in the third direction D3.

The eighth division pattern 340 may include an insulating nitride, e.g., silicon nitride.

The support patterns 210 may be spaced apart from each other along the first direction D1 on opposite sides in the second direction D2 of the first region I of the substrate 100, and may also be spaced apart from each other along the first and second directions D1 and D2 on the second region II of the substrate 100. The support patterns 210 may extend through the semiconductor layers 120, the third division structure, the eighth division pattern 340 and the conductive pads 430 to contact the upper surface of the substrate 100.

The support patterns 210 may include an insulating nitride, e.g., silicon nitride, and may be merged with the eighth division pattern 340.

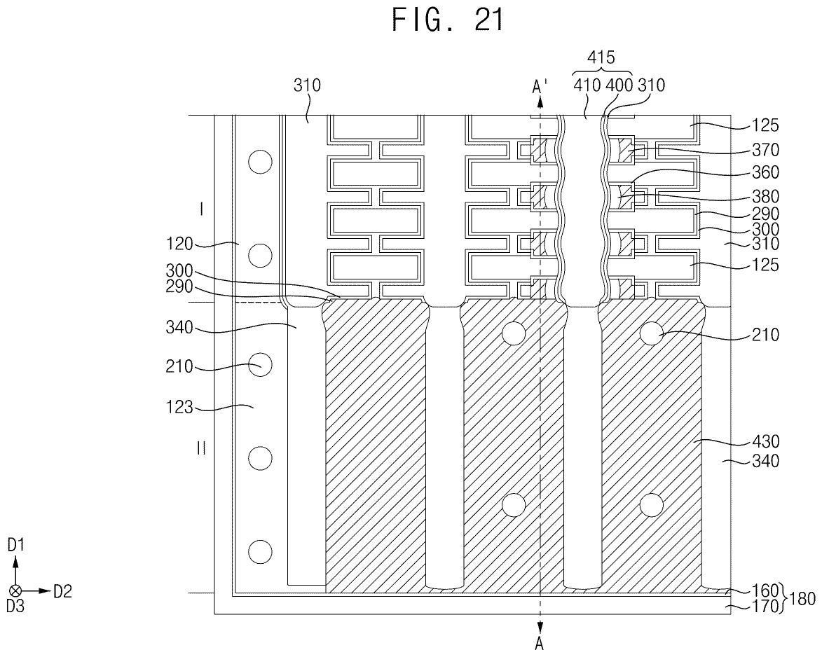

The second mask 320 may be disposed on the third division structure and the eighth division pattern 340. However, referring to FIG. 21 together with FIGS. 1 to 5, the eighth division pattern 340 may cover a sidewall of the second mask 320, and thus an upper surface of the second mask 320 may be substantially coplanar with upper surfaces of the vertical portions of the eighth division pattern 340. The second mask 320 may include an insulating nitride, e.g., silicon nitride.

The second insulating interlayer 435 may be disposed on the eighth division pattern 340 on the second region II of the substrate 100. In example embodiments, an upper surface of the second insulating interlayer 435 may be substantially coplanar with the upper surface of the second mask 320. The second insulating interlayer 435 may include an oxide, e.g., silicon oxide.

The fourth division structure 415 may be disposed between the channels 125 neighboring in the second direction D2. In example embodiments, a lower portion of the fourth division structure 415 may be disposed on the gate insulation pattern 360 covering the upper surface of the substrate 100. In example embodiments, an upper surface of an upper portion of the fourth division structure 415 may be substantially coplanar with the upper surface of the second mask 320.

The fourth division structure 415 may include a ninth division pattern 410 and a fourth insulation pattern 400 covering a sidewall and a lower surface of the ninth division pattern 410. The fourth insulation pattern 400 may include an insulating nitride, e.g., silicon nitride, and the ninth division pattern 410 may include an oxide, e.g., silicon oxide.

The bit line structures 440 may be disposed on the first region I of the substrate 100, may extend in the third direction D3 partially through the fourth division structure 415, and may be spaced apart from each other in the first direction D1. The eleventh division patterns 460 including an oxide, e.g., silicon oxide may extend partially through the fourth division structure 415 between the bit line structures 440 neighboring in the first direction D1, so that the bit line structures 440 may be separated from each other by the eleventh division patterns 460. The dummy bit line structure 450 may be disposed on a portion of the first region I adjacent to the second region II of the substrate 100.

In example embodiments, each of the bit line structure 440 and the dummy bit line structure 450 may contact the channels 125 that are disposed in the third direction D3 at each of opposite sides in the second direction D2 of each of the bit line structure 440 and the dummy bit line structure 450. Each of the bit line structures 440 and the dummy bit line structure 450 may also contact sidewalls in the second direction D2 of the gate insulation patterns 360 and the gate mask 380 that may surround the first end portions of the channels 125.

The bit line structures 440 may include first conductive patterns 441, second conductive patterns 443, and third conductive patterns 445. In example embodiments, a bit line structure 440 may include a third conductive pattern 445, a second conductive pattern 443 covering opposite sidewalls in the second direction D2 and a lower surface of the third conductive pattern 445, and a first conductive pattern 441 covering opposite outer sidewalls in the second direction D2 and a lower surface of the second conductive pattern 443.

The dummy bit line structure 450 may include a sixth conductive pattern 455, a fifth conductive pattern 453 covering opposite sidewalls in the second direction D2 and a lower surface of the sixth conductive pattern 455, and a fourth conductive pattern 451 covering opposite outer sidewalls in the second direction D2 and a lower surface of the fifth conductive pattern 453.

In example embodiments, opposite sidewalls in the first direction D1 of the first to third conductive patterns 441, 443 and 445 of the bit line structure 440 may be covered by the eleventh division patterns 460. In example embodiments, opposite sidewalls in the first direction D1 of the fourth to sixth conductive patterns 451, 453 and 455 of the dummy bit line structure 450 may be covered by the eleventh division patterns 460.

The first and fourth conductive patterns 441 and 451 may include substantially the same material, for example, a second semiconductor material doped with first impurities. The first impurities may include, for example, n-type impurities or p-type impurities (charge carrier impurities). The second semiconductor material may include, for example, silicon, germanium, or silicon-germanium.

In semiconductor technology, if a semiconductor contains both p-type and n-type impurities, the conductivity-type of the semiconductor will be determined by which type of impurity is in greater concentration. Therefore, if a semiconductor has both p-type and n-type impurities, the net conductivity type will be determined by the dominant impurity concentration. As used herein, a semiconductor region of a “first conductivity-type” denotes that the dominant impurities in the semiconductor region is (or are) a first conductivity-type impurity, and a “concentration of the first conductivity-type” in the semiconductor region (or a “doping concentration”) refers the net concentration of the impurities in the semiconductor region (i.e., (the amount of first conductivity-type impurities minus the amount of second conductivity-type impurities)/the volume of the semiconductor region).

The second and fifth conductive patterns 443 and 453 may include substantially the same material, for example, a silicide such as tungsten silicide, molybdenum silicide, titanium silicide, cobalt silicide, nickel silicide, platinum silicide, etc.

The third and sixth conductive patterns 445 and 455 may include substantially the same material, for example, a metal nitride such as titanium nitride, tungsten nitride, tantalum nitride, molybdenum nitride, etc., a metal such as tungsten, titanium, aluminum, cobalt, nickel, copper, etc., or a combination thereof.

In addition, terminal portions in the second direction D2 of the first end portions of the channels 125 adjacent to the first conductive patterns 441 may be referred to as first ohmic contacts (or conductive contacts) 125a. In an example embodiment, the first ohmic contacts 125a may further include the first impurity than the remaining portions of the channels 125 excluding first and second ohmic contacts 125a and 125b. For example, the first ohmic contacts 125a may include, for example, the first semiconductor material doped with the first impurity. In another example embodiment, the first ohmic contacts 125a may include a third semiconductor material doped with the first impurity. The third semiconductor material may include, for example, silicon, germanium, or silicon-germanium. Throughout the spec, ohmic contacts (including the first and second ohmic contacts) may be conductive contacts). The ohmic contact may be a conductive contact or a conductive pattern that enables a non-rectifying electrical junction between two conductive materials (e.g., between the channel 125 and the bit line structures 440, between the ohmic contact 125a and the channel 125, and/or between the ohmic contact 125 and the first conductive pattern 441), wherein the current-voltage characteristic is substantially linear and consistent with Ohm's law. An ohmic contact may allow bidirectional flow of charge carriers without significant rectification, voltage threshold effects, or excessive power dissipation. Preferably, it may allow substantially low electrical resistance to minimize energy loss and ensure efficient electrical conduction between the interfacing conductive regions.

In example embodiments, a cross-section of the bit line structure (or bit line) 440 extending in the first and second directions D1 and D2 and extending through a first channel among the channels 125 may have a first width W1 in the second direction D2. The first width W1 may have the minimum value at a center in the first direction D1 of the cross-section of the bit line structure 440, and may have the maximum value at each of opposite end portions in the first direction D1 of the cross-section of the bit line structure 440. For example, a cross-section extends in the first and second directions D1 and D2 and extends through a first channel among the channels 125. In the cross-section, the bit line 440 has a first width W1 in in the second direction D2. In the cross-section, the first width W1 may have the minimum value at a center of the bit line 440 in the first direction D1, and the first width W1 may have the maximum value at each of opposite end portions of the bit line 440 in the first direction D1.

In example embodiments, a cross-section of the bit line structure 440 extending in the second and third directions D2 and D3 may have a second width W2 in the second direction D2. The maximum value of the second width W2 at a height corresponding to each of the channels 125 may be smaller than the maximum value of the second width W2 at a height corresponding to portions of the third division structure disposed between the channels 125. Accordingly, the second width W2 may repeat increasing and decreasing along the third direction D3. For example, in a cross-section of the bit line extending in the second and third directions D2 and D3, the bit line 440 may have a second width W2 in the second direction D2. The second width W2 may have a width W2a at a height (vertical level) where each of the channels 125 is positioned, and the second width W2 may have a width W2b at a vertical level where isolation pattern 310 (seventh division pattern) is positioned. The width W2b may be greater than the W2a. For example, with respect to a cross-section of the bit line extending in the second and third directions D2 and D3, widths of the bit line at vertical levels corresponding to the vertical levels of the channels 125 may each be less than each of the widths of the bit line at vertical levels corresponding to the vertical levels of the isolation pattern 310.

The blocking structures 490 may extend through the third division structure between the channels 125 neighboring in the second direction D2 on the portion of the first region I adjacent to the second region II of the substrate 100, and may contact the upper surface of the substrate 100. The blocking structures 490 may be disposed at an opposite side of the bit line structures 440 with respect to the channels 125. In an example embodiment, a blocking structure 490 may have a shape of, e.g., polygon such as a rectangle in a plan view. However, the inventive concept is not limited thereto.

In example embodiments, the blocking structure 490 may include a second blocking pattern 480 extending in the third direction D3 and a first blocking pattern 470 covering a sidewall and a lower surface of the second blocking pattern 480.

The first blocking pattern 470 may include an insulating nitride, e.g., silicon nitride, and the second blocking pattern 480 may include an oxide, e.g., silicon oxide.

The capacitor structures may include capacitors 550 and plate electrodes 560, and the capacitors 550 may include first capacitor electrodes 520, second capacitor electrodes 540 and dielectric patterns 530. In example embodiments, a capacitor 550 may include a portion of a first capacitor electrode 520, a portion of a dielectric pattern 530 and a portion of a second capacitor electrode 540 sequentially stacked on a surface of the channel 125. In example embodiments, a capacitor structure may include a plate electrode 560 and capacitors 550 at opposite sidewalls in the second direction D2 of the plate electrode 560. The capacitor structure may extend in the first direction D1 on the first region I of the substrate 100.

In example embodiments, the first capacitor electrodes 520, the dielectric patterns 530 and the second capacitor electrodes 540 may be sequentially stacked in spaces between the channels 125 that are stacked in the third direction D3, between the upper surface of the substrate 100 and the lowermost channel 125, and between the second mask 320 and the uppermost channel 125 on the first region I of the substrate 100. In example embodiments, the plate electrodes 560 may fill the remaining portion of the spaces and a space between the channels 125 neighboring in the second direction D2. Thus, the plate electrode 560 may include a vertical extension portion extending in the third direction D3 and horizontal extension portions extending from opposite sidewalls in the second direction D2 of the vertical extension portion.

In example embodiments, the capacitor structures may extend through the capping layer 500 and the third division structure, and may contact sidewalls in the first direction D1 of the blocking structures 490. Thus, the capacitor structures may be disposed at an opposite side in the second direction D2 of the bit line structures 440 with respect to the channels 125.

The first and second capacitor electrodes 520 and 540 may include a metal, e.g., titanium, tantalum, etc., or a metal nitride, e.g., titanium nitride, tantalum nitride, etc. The dielectric patterns 530 may include a metal oxide having a high dielectric constant, e.g., hafnium oxide, zirconium oxide, etc. The plate electrodes 560 may include, e.g., doped or undoped silicon-germanium.

In addition, terminal portions in the second direction D2 of second end portions in the second direction D2 of the channels 125 adjacent to the first capacitor electrodes 520 may be referred to as second ohmic contacts 125b. In an example embodiment, the second ohmic contacts 125b may further include a second impurity than the remaining portions of the channels 125 excluding the first and second ohmic contacts 125a and 125b. For example, the second ohmic contacts 125b may include, for example, the first semiconductor material such as silicon doped with the second impurity. The second impurity may include, for example, n-type impurities or p-type impurities. In another example embodiment, the second ohmic contacts 125b may include a fourth semiconductor material doped with the second impurity. The fourth semiconductor material may include, for example, silicon, germanium, or silicon-germanium.

The memory cells may be arranged not only along the first and second directions D1 and D2 on the first region I of the substrate 100, but also in the third direction D3. Each of the memory cells may include the word line and the bit line structure 440 extending respectively (individually) in the first and second directions D1 and D2, the channel 125 surrounded by the word line and contacting the bit line structure 440, and the capacitor 550 electrically connected to the channel 125 on the first region I of the substrate 100.

The capping layer 500 may be disposed on the second mask 320, the second insulating interlayer 435 and the fourth division structure 415 on the substrate 100, and may cover a sidewall of upper portions of the capacitor structures. The capping layer 500 may include an insulating nitride, e.g., silicon nitride.

The third insulating interlayer 600 may be disposed on the capping layer 500.

The first contact plugs 612 may extend through the third insulating interlayer 600 and the capping layer 500 to contact upper surfaces of the bit line structures 440. The second contact plugs 614 may extend through the third insulating interlayer 600 to contact upper surfaces of the plate electrodes 560 of the capacitor structures. The third contact plugs 616 may extend through the third insulating interlayer 600, the capping layer 500, the second mask 320 and the eighth division pattern 340 or extend through the third insulating interlayer 600, the capping layer 500 and the second insulating interlayer 435 to contact upper surfaces of the conductive pads 430.

In the semiconductor device, the bit line structure 440 may include the first, second, and third conductive patterns 441, 443 and 445 sequentially stacked on sidewalls in the second direction D2 of the first end portions of the channels 125 that are spaced apart from each other in the third direction D3.

The first ohmic contacts 125a may be formed by diffusion of the first impurity of the first conductive pattern 441 towards the terminal portions in the second direction D2 of the first end portions of the channels 125. This approach provides more uniform impurity concentration along the third direction D3 as compared to forming the first ohmic contacts 125a using a vapor phase doping process.

Additionally, the second and third conductive patterns 443 and 445 exhibit lower resistance at low temperatures than the first conductive pattern 441, which is a semiconductor layer. As a result, the bit line structure 440 achieves improved resistance characteristics as compared to a configuration where the bit line structure 440 consists of only the first conductive pattern 441.

Furthermore, the second conductive pattern 443 including a silicide may be disposed between the first conductive pattern 441, which is a semiconductor layer, and the third conductive pattern 445, which is a metal nitride layer or metal layer, effectively reducing the contact resistance between these layers.

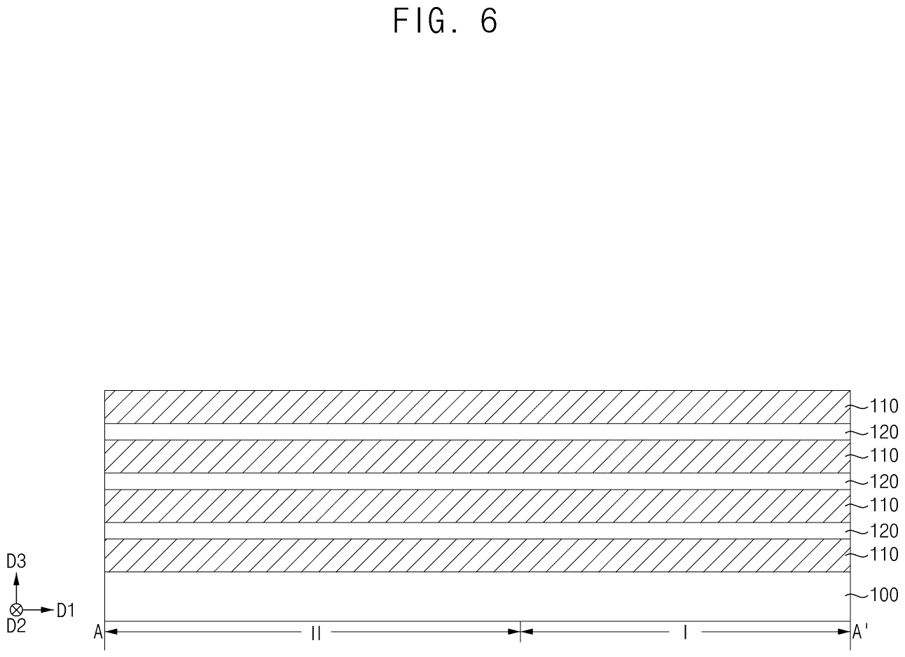

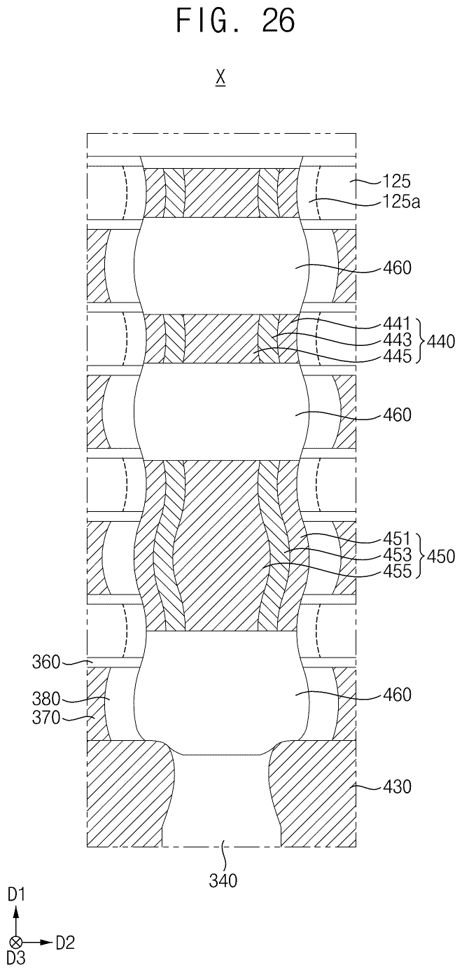

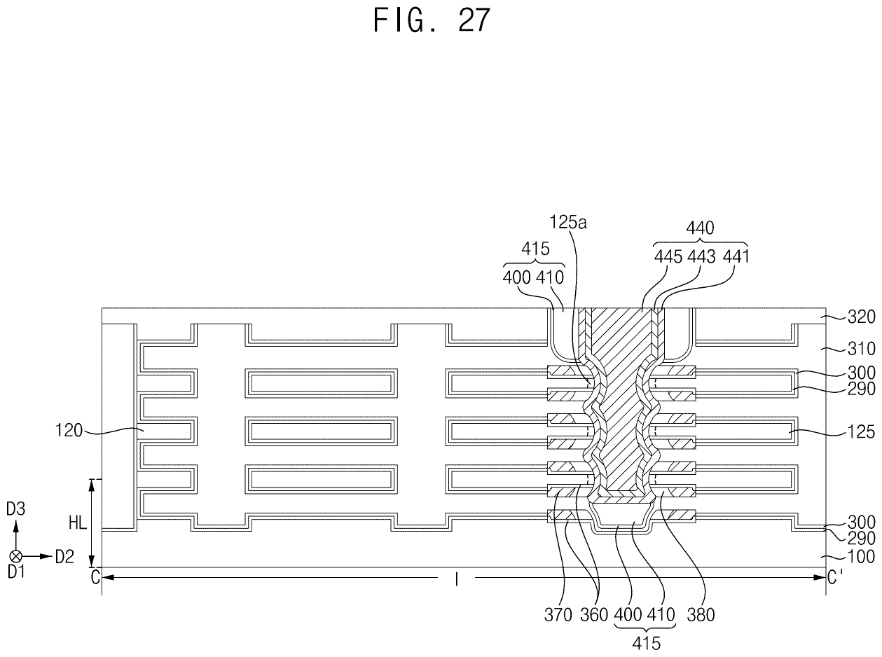

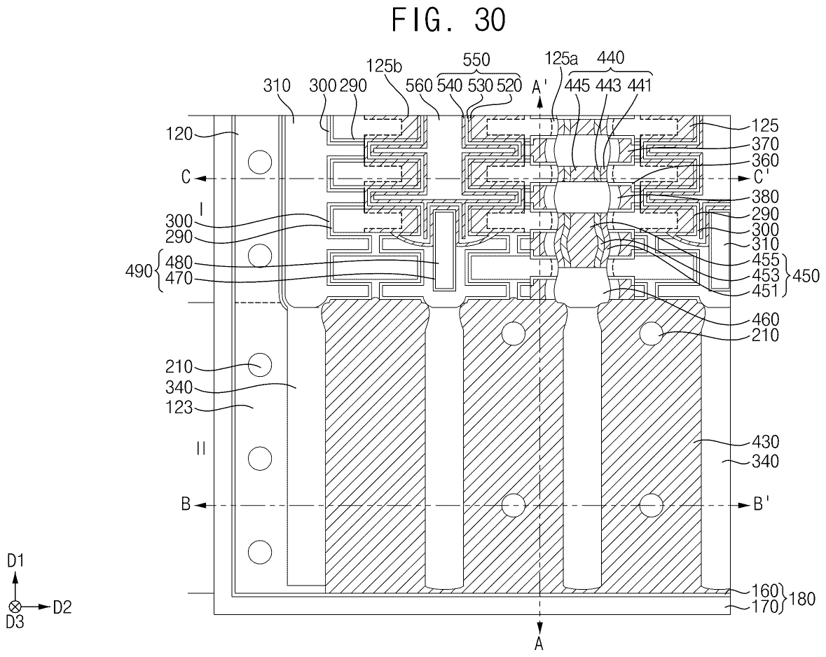

FIGS. 6 to 31 are vertical cross-sectional views and horizontal cross-sectional views illustrating a method of manufacturing a semiconductor device in accordance with example embodiments.

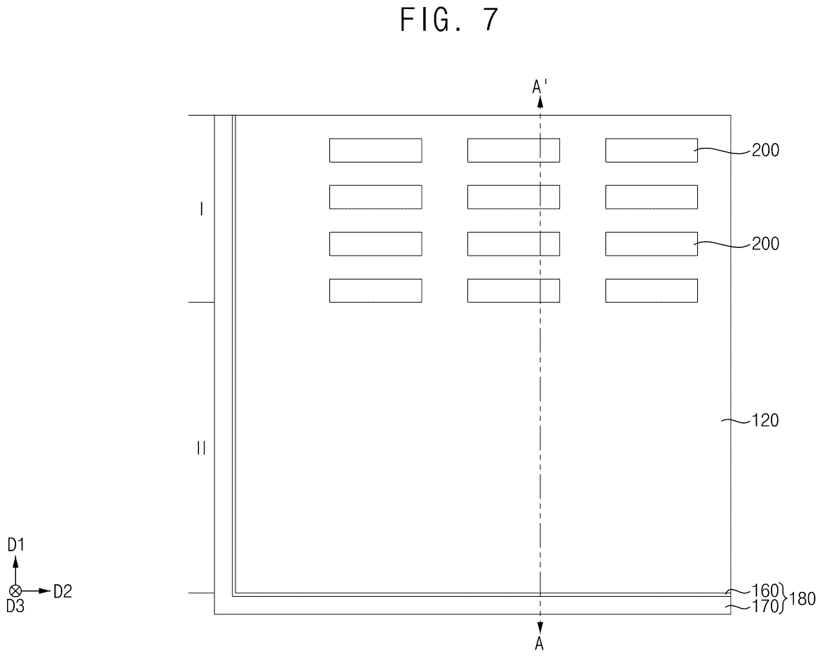

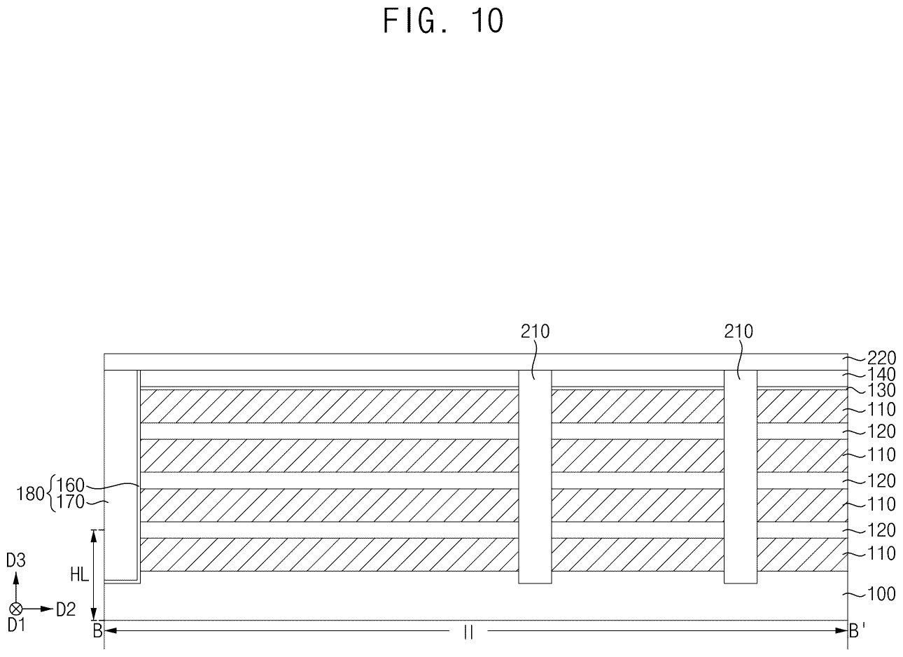

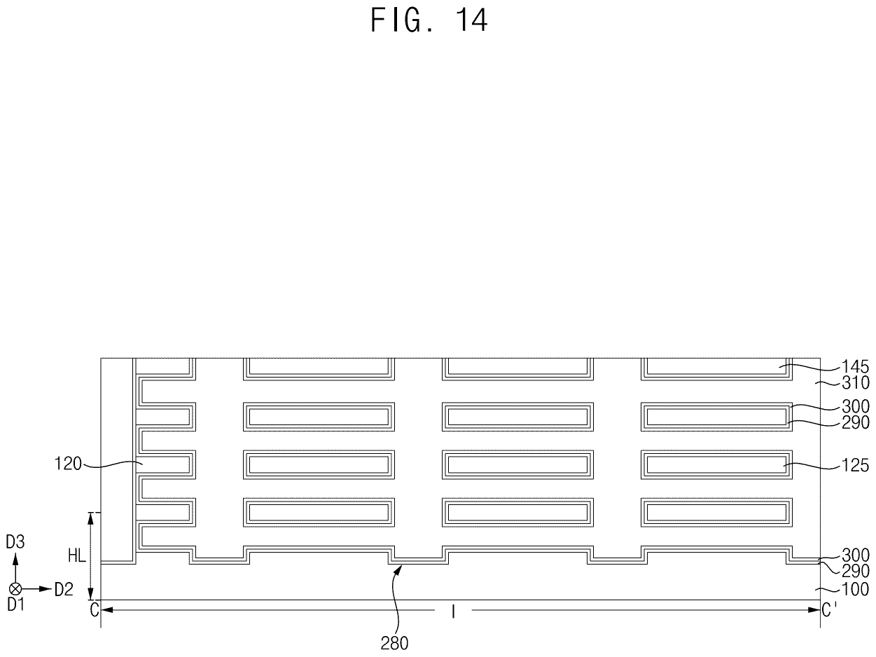

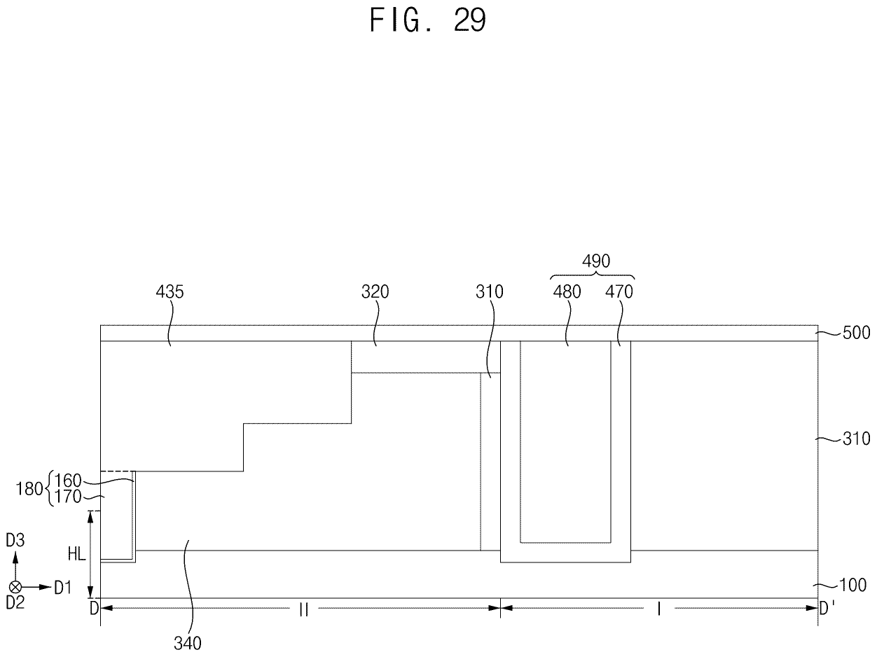

Particularly, FIGS. 7, 9, 11, 13, 15, 17, 19, 21, 23-26, 28 and 30 are horizontal cross-sectional views at heights (vertical levels) HL of corresponding vertical cross-sectional views, respectively. FIGS. 6, 8 and 22 are vertical cross-sectional views taken along lines A-A′ of corresponding horizontal cross-sectional views, respectively. FIGS. 10, 12, 16 and 20 are vertical cross-sectional views taken along lines B-B′ of corresponding horizontal cross-sectional views, respectively. FIGS. 14, 18, 27 and 31 are vertical cross-sectional views taken along lines C-C′ of corresponding horizontal cross-sectional views, respectively. FIG. 29 are vertical cross-sectional views taken along lines D-D′ of corresponding horizontal cross-sectional views, respectively.

Referring to FIG. 6, sacrificial layers 110 and semiconductor layers 120 may be alternately and repeatedly stacked on a substrate 100 to form a mold layer.

FIG. 6 shows that the sacrificial layers 110 and the semiconductor layers 120 are stacked at four levels and three levels, respectively (e.g., individually), on the substrate 100. However, the inventive concept is not limited thereto, and the sacrificial layers 110 and the semiconductor layers 120 may be stacked at more or less than four levels and three levels, respectively (e.g., individually).

In example embodiments, the mold layer may be formed by an epitaxial growth process using an upper surface of the substrate 100 as a seed.

In an example embodiment, the semiconductor layers 120 may include, e.g., silicon, and the sacrificial layers 110 may include a material having a selectivity with respect to the semiconductor layers 120, e.g., silicon-germanium.

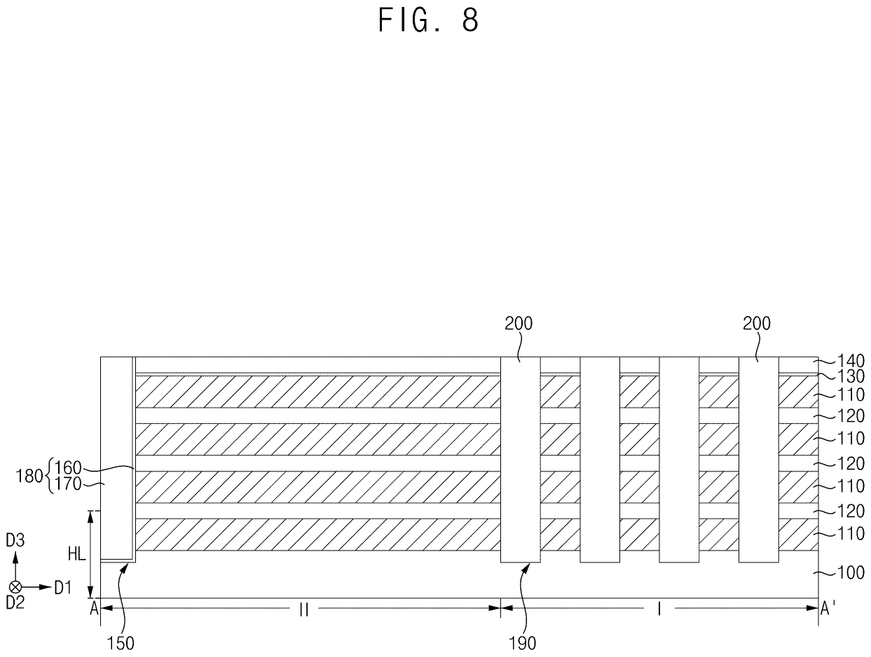

Referring to FIGS. 7 and 8, an insulation pad layer 130 and a first mask layer 140 may be sequentially stacked in the third direction D3 on the mold layer, a dry etching process may be performed on the first mask layer 140, the insulation pad layer 130 and the mold layer to form a first opening 150 exposing the upper surface of the substrate 100, and a first division structure 180 may be formed in the first opening 150.

The insulation pad layer 130 may include an oxide, e.g., silicon oxide, and the first mask layer 140 may include an insulating nitride, e.g., silicon nitride.

In example embodiments, the first division structure 180 may have a lattice shape in a plan view, and thus a plurality of memory block regions each of which may have, e.g., a rectangular shape may be defined in each of the first and second directions D1 and D2 on the memory cell region of the substrate 100. However, the inventive concept is not limited thereto, and each of the memory block regions may have other shapes in a plan view. FIG. 7 shows a portion of the first division structure 180.

In example embodiments, each of the memory block regions may include first and second regions I and II arranged in the first direction D1.

In an example embodiment, the first division structure 180 may include a first division pattern 160 on a sidewall and a bottom of the first opening 150 and a second division pattern 170 fill the remaining portion of the first opening 150. A sidewall and a lower surface of the second division pattern 170 may be covered by the first division pattern 160. The first division pattern 160 may include an insulating nitride, e.g., silicon nitride, and the second division pattern 170 may include an oxide, e.g., silicon oxide.

For example, a dry etching process may be performed on the first mask layer 140, the insulation pad layer 130 and the mold layer to form second openings 190 exposing the upper surface of the substrate 100, and third division patterns 200 may be formed in the second openings 190.

In example embodiments, the third division patterns 200 may have a bar shape extending in the second direction D2 in a plan view, and may be spaced apart from each other in each of the first and second directions D1 and D2. The third division patterns 200 may include an oxide, e.g., silicon oxide.

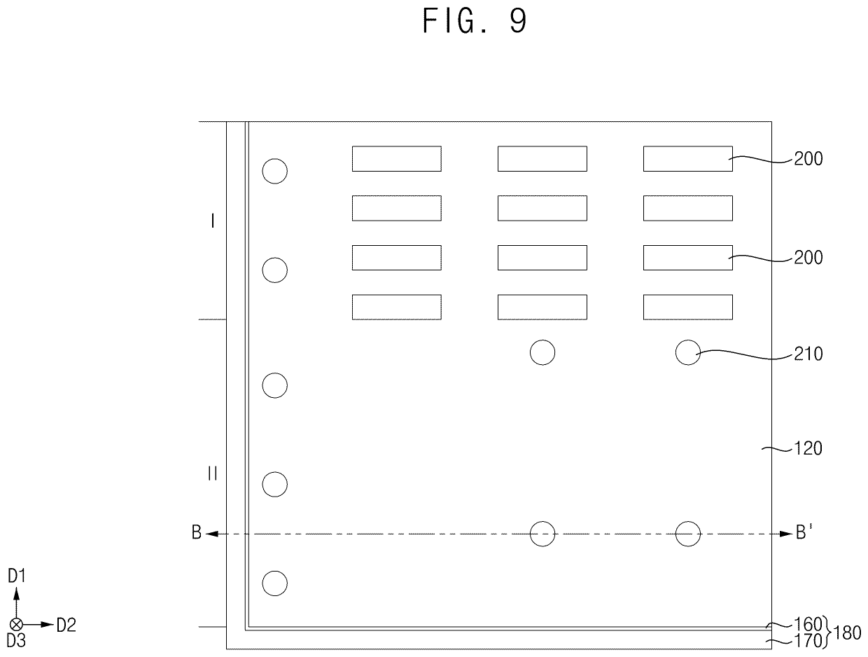

Referring to FIGS. 9 and 10, a dry etching process may be performed on the first mask layer 140, the insulation pad layer 130 and the mold layer to form third openings exposing the upper surface of the substrate 100, and support patterns 210 may be formed in the third openings.

In example embodiments, the support patterns 210 may have a shape of, e.g., a circle, an ellipse, a polygon, a polygon with rounded corners, etc., in a plan view, and may be spaced apart from each other in each of the first and second directions D1 and D2. The support patterns 210 may include an insulating nitride, e.g., silicon nitride.

A first insulating interlayer 220 may be formed on the first mask layer 140, the first division structure 180, the third division patterns 200 and the support patterns 210. The first insulating interlayer 220 may include an oxide, e.g., silicon oxide.

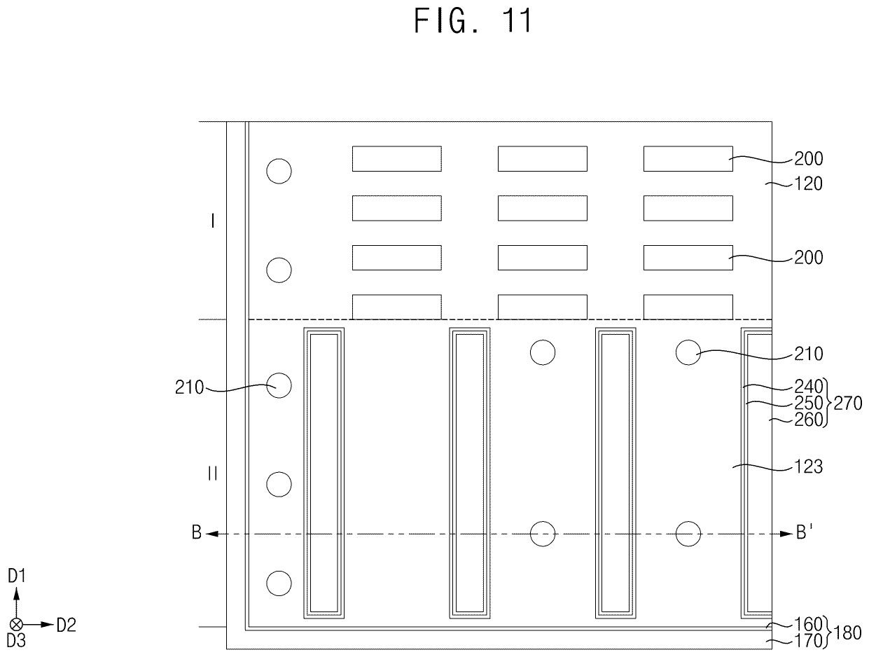

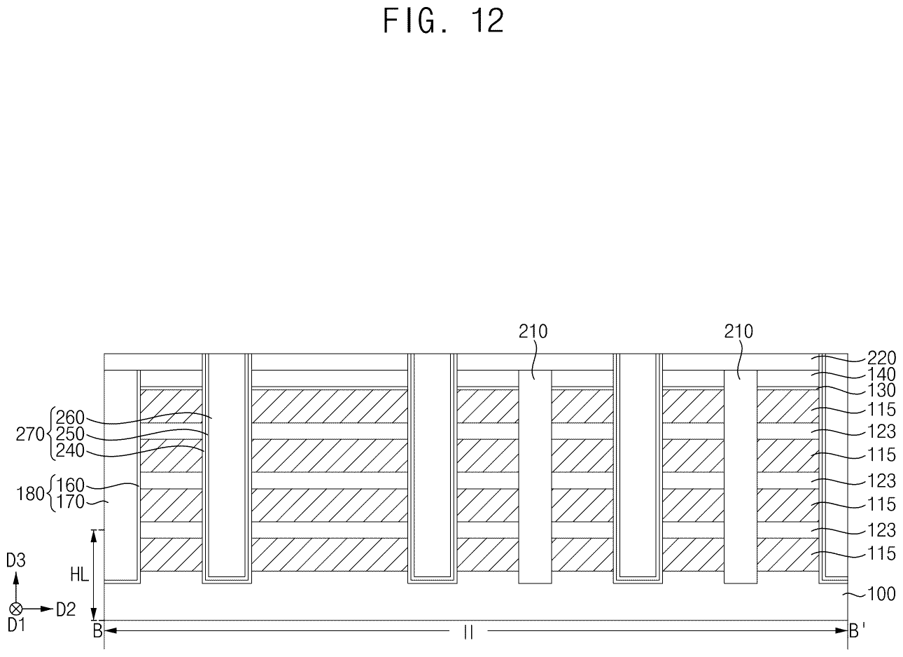

Referring to FIGS. 11 and 12, a dry etching process may be performed on the first insulating interlayer 220, the first mask layer 140, the insulation pad layer 130 and the mold layer to form fourth openings 230 exposing the upper surface of the substrate 100, and second division structures 270 may be formed in the fourth openings 230.

In example embodiments, the second division structures 270 may have a bar shape extending in the first direction D1 in a plan view, and may be spaced apart from each other in the second direction D2. In example embodiments, a second division structure 270 may overlap in the first direction D1 a portion of the mold layer between the third division patterns 200 neighboring in the second direction D2.

In an example embodiment, the second division structure 270 may include fourth to sixth division patterns 240, 250 and 260 sequentially stacked from a sidewall and a bottom of a fourth opening 230. Each of the fourth and sixth division patterns 240 and 260 may include an oxide, e.g., silicon oxide, and the fifth division pattern 250 may include an insulating nitride, e.g., silicon nitride.

As the second division structures 270 are formed, portions of the sacrificial layers 110 and the semiconductor layers 120 included in a portion of the mold layer on the second region II of the substrate 100 may be transformed into first sacrificial patterns 115 and semiconductor patterns 123, respectively (e.g., individually).

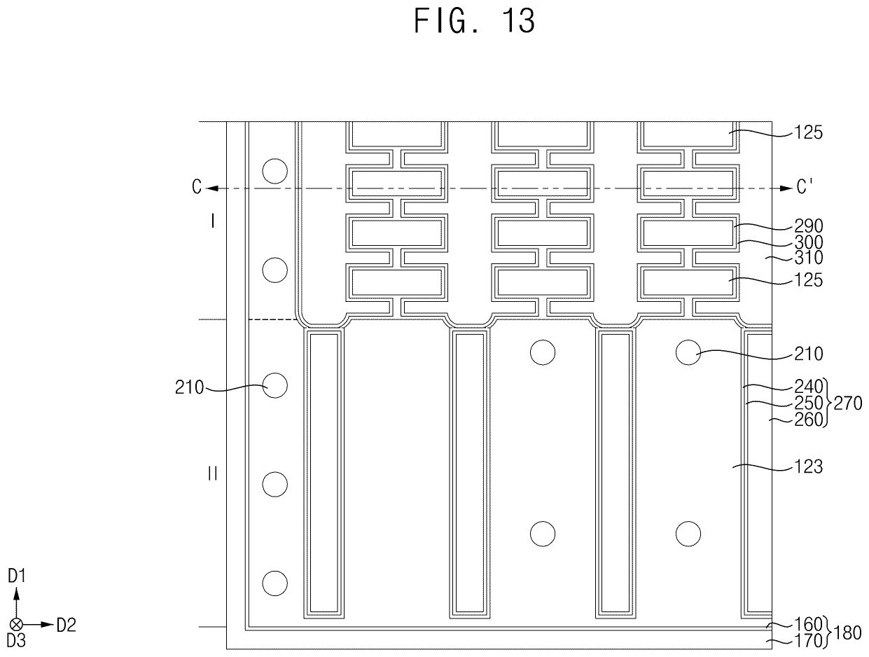

Referring to FIGS. 13 and 14, a dry etching process may be performed on the first insulating interlayer 220, the first mask layer 140, the insulation pad layer 130 and the mold layer to form fifth openings 280 exposing the upper surface of the substrate 100.

In example embodiments, the fifth openings 280 may extend in the first direction D1 between the third division patterns 200 neighboring in the second direction D2, and a may be spaced apart from each other in the second direction D2 in the first region I. A fifth opening 280 may be aligned with the second division structure 270 in the first direction D1, and may extend through a portion of the fourth division pattern 240 at an end portion in the first direction D1 of the second division structure 270 to expose a sidewall of the fifth division pattern 250.

As the fifth openings 280 are formed, portions of the sacrificial layers 110 and the semiconductor layers 120 between the third division patterns 200 neighboring in the first direction D1 and between the fifth openings 280 on the memory cell region of the substrate 100 may be transformed into second sacrificial patterns and channels 125, respectively (e.g., individually), and portions of the insulation pad layer 130 and the first mask layer 140 on an uppermost second sacrificial pattern may remain as an insulation pad and a first mask 145.

A wet etching process may be performed through the fifth openings 280 to remove portions of the second sacrificial patterns in the first region I, and most portions of the third division patterns 200 adjacent to the fifth openings 280 in the first region I and the insulation pad may also be removed.

Thus, first gaps may be formed between the channels 125 neighboring in the third direction D3, between an uppermost channel 125 and the first mask 145, and between a lowermost channel 125 and the upper surface of the substrate 100. Additionally, the first gaps may be enlarged in the first direction D1, so that portions of the third division patterns 200 at the same level as the channels 125 may remain, and other portions of the third division patterns 200 may be removed.

First and second insulation layers may be sequentially stacked on inner walls of the first gaps, sidewalls and bottoms of the fifth openings 280 and the first insulating interlayer 220, a seventh division layer may be formed on the second insulation layer to fill the first gaps and the fifth openings 280, and a planarization process may be performed on the seventh division layer, the first and second insulation layers, the first insulating interlayer 220 and the second division structures 270 until an upper surface of the first mask 145 is exposed. Thus, a third division structure including first and second insulation patterns 290 and 300 and a seventh division pattern 310 may be formed in the first gaps and the fifth openings 280, and the first insulating interlayer 220 may be removed.

The first insulation pattern 290 and the seventh division pattern 310 may include an oxide, e.g., silicon oxide, and the second insulation pattern 300 may include an insulating nitride, e.g., silicon nitride. The third division pattern 200 remaining between the channels 125 may be merged with the first insulation pattern 290, and hereinafter, the merged structure may be referred to as a first insulation pattern 290. In some embodiments, the first insulation pattern 290 and a portion of the fourth division pattern 240 exposed by the fifth opening 280 may contact each other to be merged with each other.

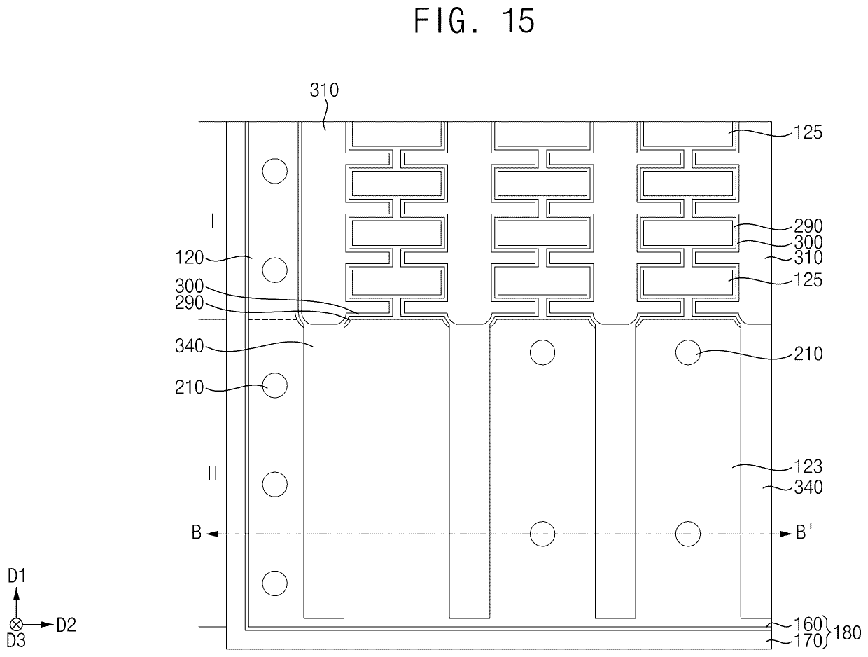

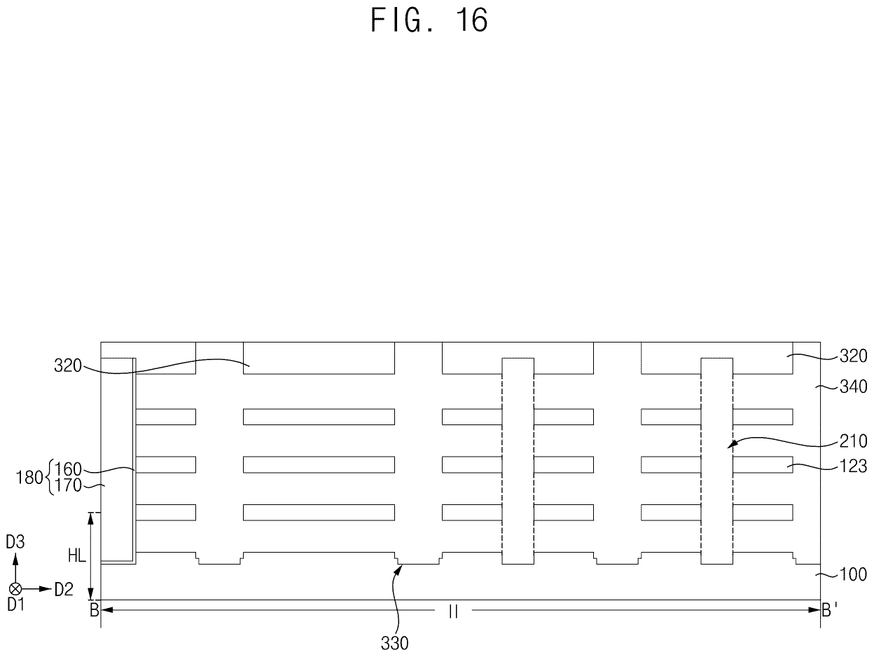

Referring to FIGS. 15 and 16, a second mask 320 may be formed on the first mask layer 140, the first mask 145, the second division structures 270 and the third division structure, a dry etching process may be performed using the second mask 320 as an etching mask to remove the second division structures 270 so that sixth openings 330 exposing the upper surface of the substrate 100 may be formed. Portions of the first sacrificial patterns 115 adjacent to the sixth openings 330 may be removed through the sixth openings 330, and the insulation pad layer 130 may also be removed.

Thus, second gaps may be formed between the semiconductor patterns 123 neighboring in the third direction D3, between an uppermost semiconductor pattern 123 and the first mask layer 140, and between a lowermost semiconductor pattern 123 and the substrate 100.

The second mask 320 may include an insulating nitride, e.g., silicon nitride, and the first mask layer 140 and the first mask 145 may be merged to the second mask 320. Hereinafter, the merged structure may be referred to as the second mask 320.

An eighth division layer may be formed on the substrate 100 and the second mask 320 to fill the second gaps and the sixth openings 330, and a planarization process may be performed on the eighth division layer until an upper surface of the second mask 320 is exposed to form an eighth division pattern 340 in the second gaps and the sixth openings 330. The eighth division pattern 340 may include an insulating nitride, e.g., silicon nitride, and thus, in some embodiments, the support patterns 210 may be merged to the eighth division pattern 340.

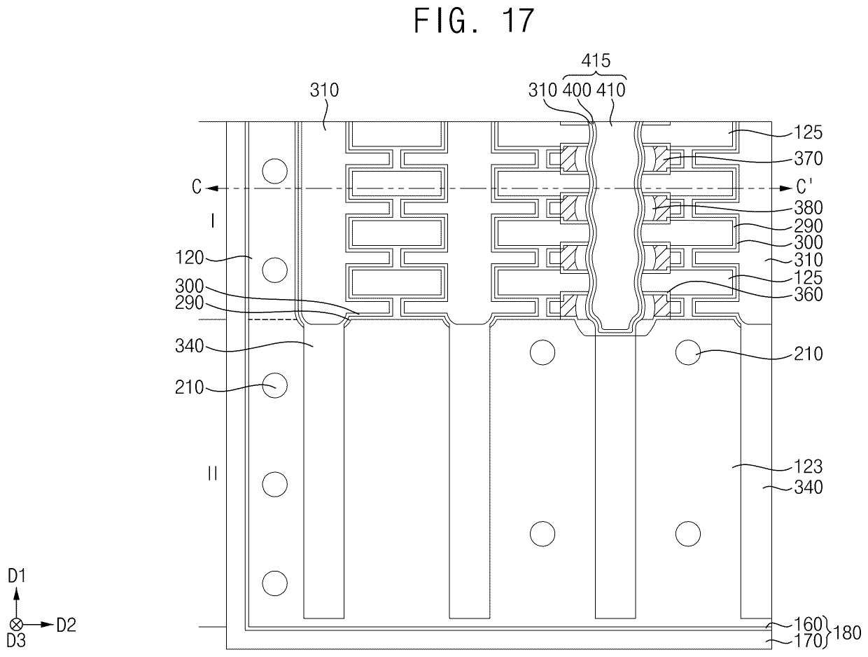

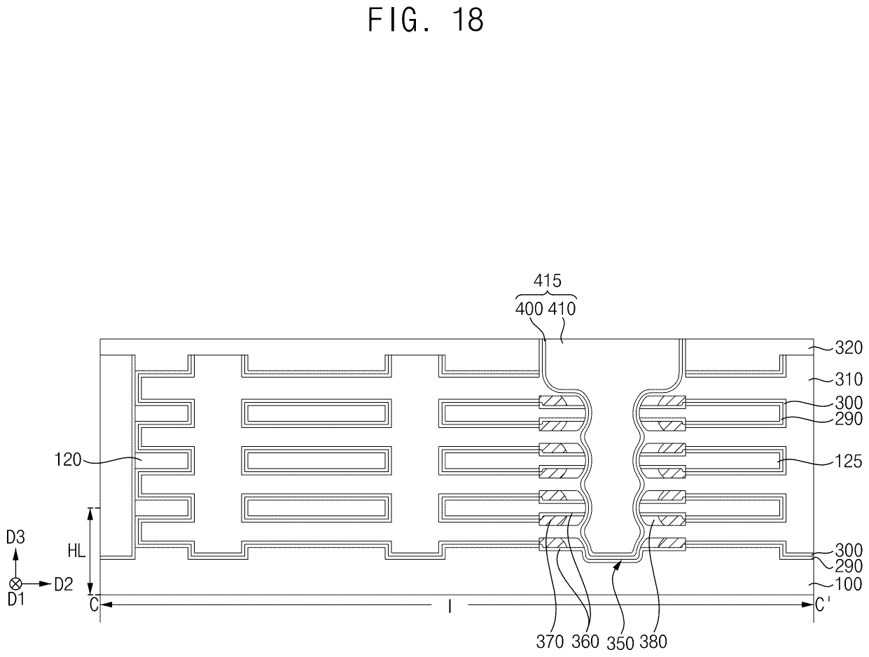

Referring to FIGS. 17 and 18, the second mask 320 and the third division structure may be partially removed by, e.g., a dry etching process to form a seventh opening 350 exposing the upper surface of the substrate 100.

For example, a wet etching process may be performed through the seventh opening 350, and portions of the third division structure that are adjacent to the seventh opening 350 and disposed between the channels 125 neighboring each other in the third direction D3 may be removed to form fourth gaps. Accordingly, first end portions in the second direction D2 of the channels 125 may be exposed.

For example, a thermal oxidation process may be performed to form gate insulation patterns 360 covering the upper surface of the substrate 100 and upper and lower surfaces and sidewalls of the first end portions of the channels 125 exposed by the seventh opening 350 and the fourth gaps.

A gate electrode layer may be formed on the gate insulation patterns 360, and a wet etching process or a dry etching process may be performed on the gate electrode layer to form gate electrodes 370 surrounding portions of the gate insulation patterns 360.

A gate mask layer may be formed on the gate insulation patterns 360 and the gate electrodes 370, and a wet etching process or a dry etching process may be performed on the gate mask layer to form gate masks 380 surrounding portions of the gate insulation patterns 360 and respectively (e.g., individually) contacting sidewalls in the second direction D2 of the gate electrodes 370.

The gate electrodes 370, the gate insulation patterns 360, and the gate masks 380 may collectively form gate structures on the memory cell region of the substrate 100. Each of the gate electrodes 370 may extend in the first direction D2 to surround the first end portions in the second direction D2 of the channels 125 in the first region I. Thus, the gate structures may be spaced apart from each other in the third direction D3 at each of opposite sides in the second direction D2 of the seventh opening 350. Each of the gate structures may serve as a word line of the semiconductor device.

Buried patterns may be formed to fill spaces between the gate structures spaced apart from each other in the third direction D3, a third insulation layer and a fourth insulation layer may be sequentially stacked on sidewalls in the second direction D2 of the gate structures adjacent to the seventh opening 350, sidewalls of the buried patterns and the upper surface of the substrate 100 exposed by the seventh opening 350, a ninth division layer may be formed to fill the seventh opening 350, and a planarization process may be performed on the third insulation layer, the fourth insulation layer and the ninth division layer until the upper surface of the second mask 320 is exposed to form a third insulation pattern, a fourth insulation pattern 400 and a ninth division pattern 410, respectively (e.g., individually).

The buried patterns, the third insulation pattern and the ninth division pattern 410 may include an oxide, e.g., silicon oxide, and the fourth insulation pattern 400 may include an insulating nitride, e.g., silicon nitride.

The buried patterns and the third insulation pattern may be merged with the seventh division pattern 310, and hereinafter, the merged structure may be referred to as the seventh division pattern 310. The fourth insulation pattern 400 and the ninth division pattern 410 may collectively form a fourth division structure 415.

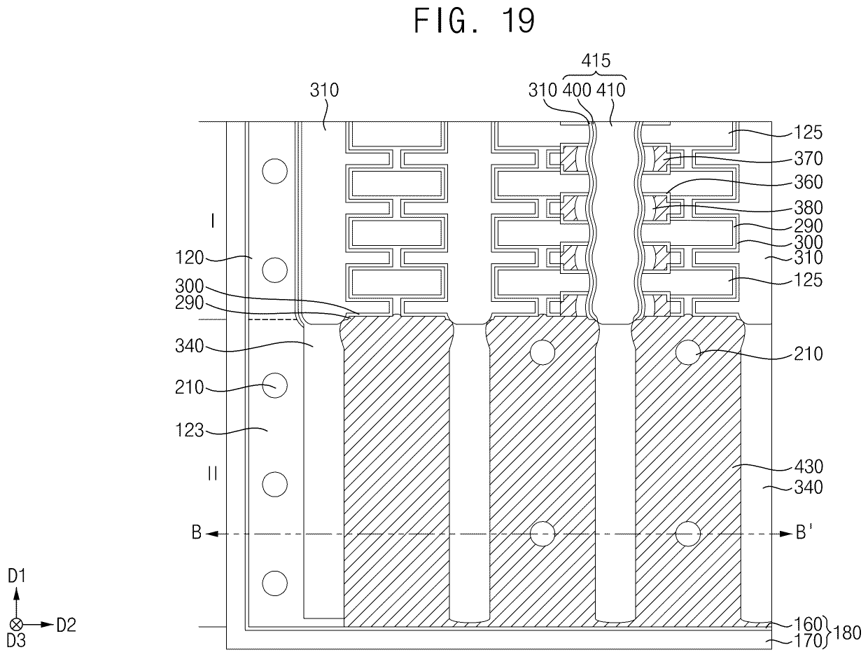

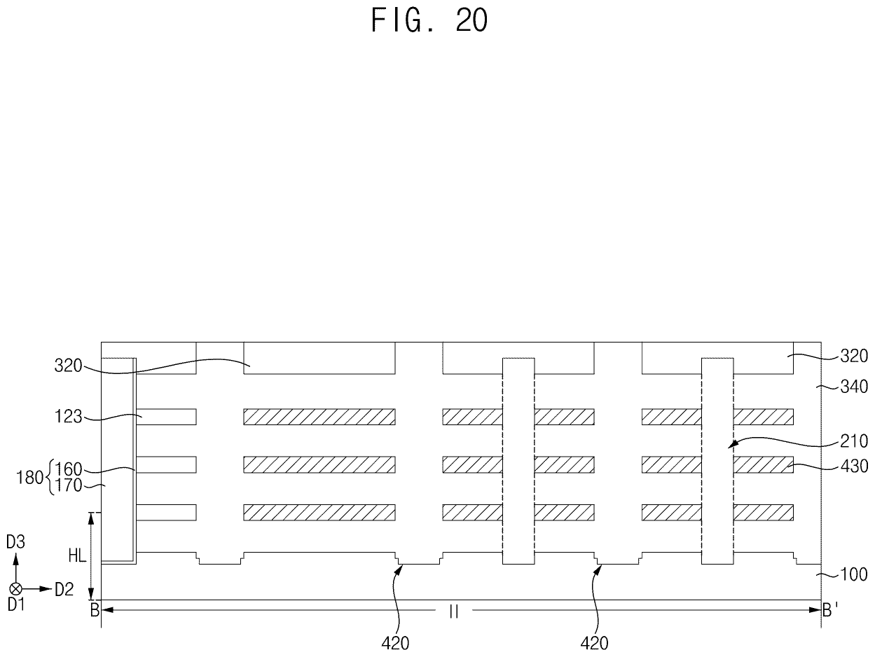

Referring to FIGS. 19 and 20, the eighth division pattern 340 may be removed by, e.g., a dry etching process to form eighth openings 420 exposing the upper surface of the substrate 100, and e.g., a wet etching process may be performed through the eighth openings 420 to remove the semiconductor patterns 123 to form third gaps, a conductive pad layer may be formed to fill the third gaps, and e.g., a wet etching process may be performed on the conductive pad layer to form conductive pads 430 in the third gaps.

In example embodiments, the conductive pads 430 may extend in the first direction D1 in the second region II, and may be spaced apart from each other in the second direction D2. Additionally, the conductive pads 430 may be spaced apart from each other in the third direction D3.

A tenth division layer may be formed to fill the eighth openings 420, and a planarization process may be performed on the tenth division layer until the upper surface of the second mask 320 is exposed to form tenth division patterns in the eighth openings 420. The tenth division patterns may include an insulating nitride, e.g., silicon nitride, and may contact portions of the eighth division pattern 340 between the conductive pads 430 spaced apart from each other in the third direction D3 to be merged thereto. Hereinafter, the portions of the eighth division pattern 340 together with the tenth division patterns merged thereto may be referred to as the eighth division pattern 340.

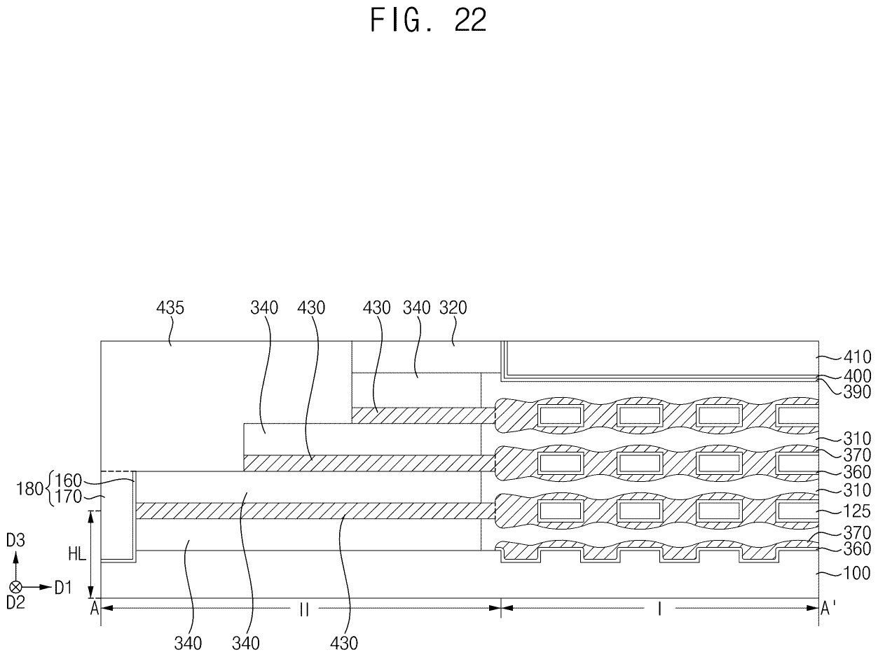

Referring to FIGS. 21 and 22, the second mask 320, the eighth division pattern 340 and the conductive pads 430 in the second region II may be partially removed by, e.g., a dry etching process to form a ninth opening exposing an upper surface of the eighth division pattern 340.

In example embodiments, after the dry etching process, each of the conductive pads 430 and a portion of the eighth division pattern 340 thereon may collectively form a step layer extending in the first direction D1, and a stack structure including the conductive pads 430 and the eighth division pattern 340 may have a staircase structure having a length decreasing from a bottom toward a top thereof in a stepwise manner. During the dry etching process, upper portions of the first and second division patterns 160 and 170 contacting end portions in the first direction D1 of the conductive pads 430 may also be removed.

A second insulating interlayer 435 may be formed to fill the ninth opening. The second insulating interlayer 435 may include an oxide, e.g., silicon oxide, and in some embodiments, may be merged to the second division pattern 170.

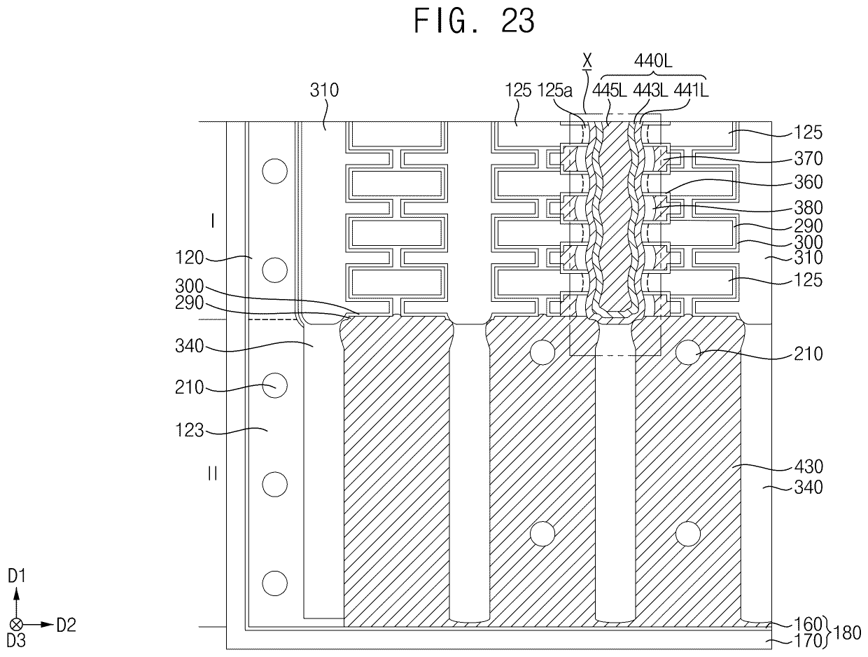

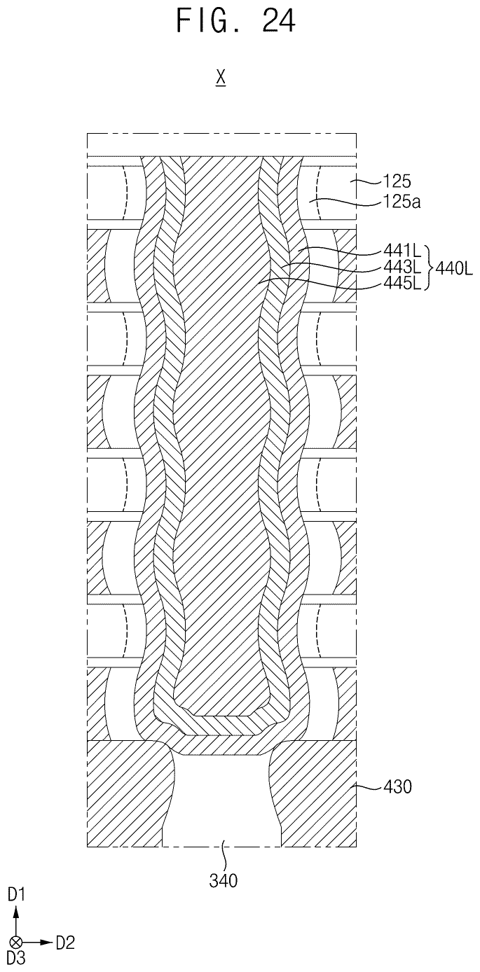

Referring to FIGS. 23 to 24, the fourth division structure 415 and the seventh division pattern 310 may be partially etched by, e.g., a dry etching process on the memory cell region of the substrate 100 to form a first trench. As the first trench is formed, terminal portions in the second direction D2 of the first end portions of the channels 125, the gate insulation patterns 360 and the gate masks 380 that are disposed in the third direction D3 at each of opposite sides in the second direction D2 of the fourth division structure 415 may be exposed.

A bit line layer structure 440L may be formed in the first trench. The bit line layer structure 440L may include first, second, and third conductive layers 441L, 443L and 445L sequentially stacked on a bottom and an inner sidewall of the first trench. The first conductive layer 441L may include, for example, a second semiconductor material doped with a first impurity. The second semiconductor material may include, for example, silicon, germanium, or silicon-germanium. The first impurity may include, for example, n-type impurities or p-type impurities.

The second conductive layer 443L may include a silicide, for example, tungsten silicide, molybdenum silicide, titanium silicide, cobalt silicide, nickel silicide, platinum silicide, etc.

The third conductive layer 445L may include a metal nitride, for example, titanium nitride, tungsten nitride, tantalum nitride, molybdenum nitride, etc., a metal, for example, tungsten, titanium, aluminum, cobalt, nickel, copper, etc., or a combination thereof.

The first conductive layer 441L may contact the terminal portions in the second direction D2 of the first end portions of the channels 125, the gate insulation patterns 360 and the gate masks 380 that are disposed in the third direction D3 at each of the opposite sides in the second direction D2 of the fourth division structure 415 exposed by the first trench

The first impurity of the first conductive layer 441L may diffuse into the terminal portions in the second direction D2 of the first end portions of the channels 125. Accordingly, the terminal portions in the second direction D2 of the first end portions of the channels 125 may be formed to further include the first impurity, and may be referred to as first ohmic contacts 125a.

Alternatively, the terminal portions in the second direction D2 of the first end portions of the channels 125 exposed by the first trench may be removed to form first recesses, and the first recesses may be filled with a third semiconductor material. In this case, the first ohmic contacts 125a may be formed to include the third semiconductor material doped with the first impurity. The third semiconductor material may include, for example, silicon, germanium, or silicon-germanium.

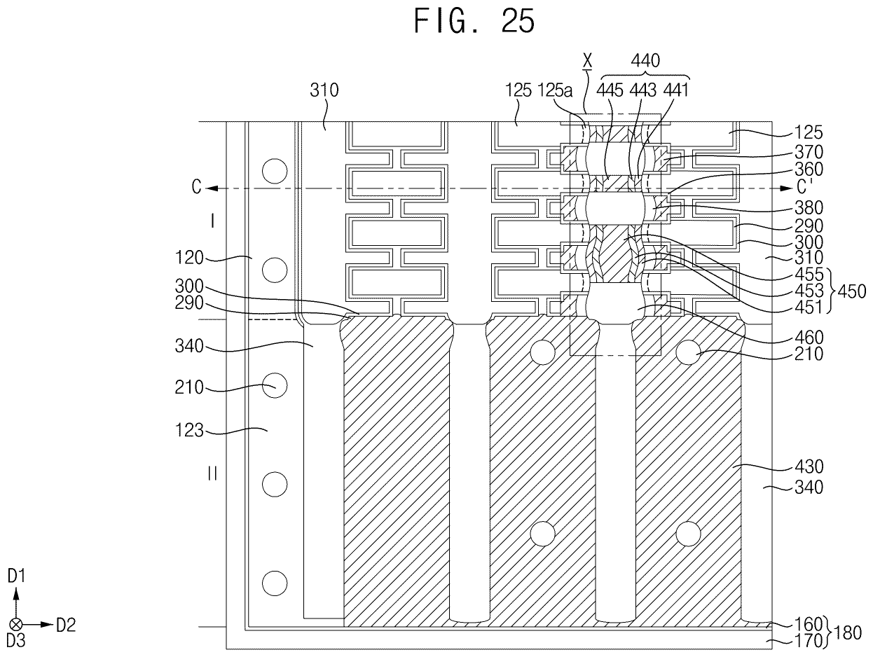

Referring to FIGS. 25 to 27, a patterning process may be performed on the bit line layer structure 440L. Accordingly, the first to third conductive layers 441L, 443L and 445L may be transformed into a plurality of first conductive patterns 441, a plurality of second conductive patterns 443, and a plurality of third conductive patterns 445, respectively (e.g., individually), and the bit line layer structure 440L may be transformed into a plurality of bit line structures 440. In example embodiments, each of the bit line structures 440 may include first to third conductive patterns 441, 443 and 445 sequentially stacked in the first trench.

In example embodiments, the bit line structures 440 may extend in the third direction D3 in the first trench, and may be spaced apart from each other along the first direction D1 in the first region I. In example embodiments, the bit line structures 440 may respectively (e.g., individually) contact the channels 125 disposed in the first direction D1 to be electrically connected thereto. However, one of the bit line structures 440 disposed in the first direction D1 that is adjacent to the second region II may be a dummy bit line structure 450.

In example embodiments, the second and first conductive patterns 443 and 441 may be sequentially stacked on opposite sidewalls in the second direction D2 of the third conductive pattern 445. In example embodiments, the third conductive pattern 445 may be formed to extend in the third direction D3. In example embodiments, the second conductive pattern 443 may be formed to cover the opposite sidewalls in the second direction D2 of the third conductive pattern 445 and a lower surface of the third conductive pattern 445. In example embodiments, the first conductive pattern 441 may be formed to cover opposite outer sidewalls in the second direction D2 of the second conductive pattern 443 and a lower surface of the second conductive pattern 443.

The dummy bit line structure 450 may include fourth, fifth, and sixth conductive patterns 451, 453 and 455. The fourth, fifth, and sixth conductive patterns 451, 453 and 455 may be formed by performing the patterning process on the first to third conductive layers 441L, 443L and 445L.

Eleventh division patterns 460 may be formed to fill spaces between the bit line structures 440 disposed in the first direction D1 on the memory cell region of the substrate 100. The eleventh division patterns 460 may include an oxide, for example, silicon oxide.

In example embodiments, the eleventh division patterns 460 may cover opposite sidewalls in the first direction D1 of the first to sixth conductive patterns 441, 443, 445, 451, 453 and 455.

In addition, an eleventh division layer may be formed in the first trench, and a patterning process may be performed on the eleventh division layer to form bit line holes, and the bit line structures 440 may be formed within the bit line holes. However, in this case, the first and second conductive patterns 441 and 443 may be formed not only on the opposite sidewalls in the second direction D2 of the third conductive pattern 445, but also on opposite sidewalls in the first direction D1 of the third conductive pattern 445. As compared to the processes described with reference to FIGS. 23 to 27, this approach results in a relatively smaller volume of the third conductive pattern 445, leading to higher resistance in the bit line structures 440. In contrast, when the bit line structures 440 are formed using the processes described with reference to FIGS. 23 to 27, the first and second conductive patterns 441 and 443 are formed only on the opposite sidewalls in the second direction D2 of the third conductive pattern 445. This configuration preserves a larger volume for the third conductive pattern 445, thereby achieving the bit line structures 440 with relatively lower resistance.

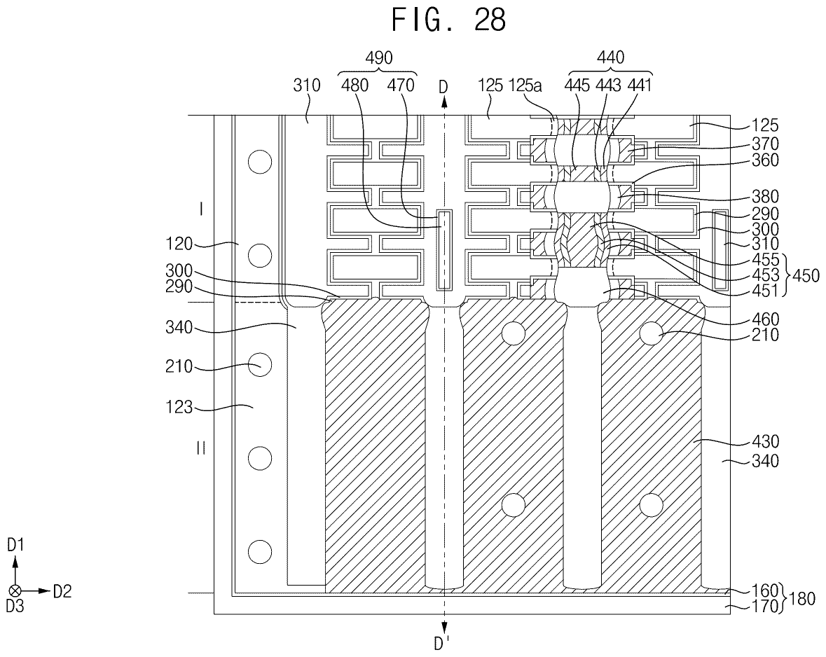

Referring to FIGS. 28 and 29, the seventh division pattern 310 may be partially removed by, e.g., a dry etching process to form tenth openings exposing the upper surface of the substrate 100, and blocking structures 490 may be formed in the tenth openings.

In example embodiments, the blocking structures 490 may be formed in a portion of the first region I adjacent to the second region II, and may be disposed between the channels 125 neighboring in the second direction D2 and at an opposite side in the second direction D2 of the bit line structure 440 with respect to the channel 125.

In an example embodiment, a blocking structure 490 may include a first blocking pattern 470 on a sidewall and a bottom of the tenth opening and a second blocking pattern 480 filling the remaining portion of the tenth opening. A sidewall and a lower surface of the second blocking pattern 480 may be covered by the first blocking pattern 470. The first blocking pattern 470 may include an insulating nitride, e.g., silicon nitride, and the second blocking pattern 480 may include an oxide, e.g., silicon oxide.

In an example embodiment, the blocking structure 490 may have a shape of a polygon, e.g., a rectangle in a plan view. However, the inventive concept is not limited thereto.

A capping layer 500 may be formed on the blocking structures 490, the bit line structures 440, the dummy bit line structure 450, the second insulating interlayer 435, the second mask 320, the seventh division pattern 310, the fourth division structure 415 and the eleventh division patterns 460. The capping layer 500 may include an insulating nitride, e.g., silicon nitride.

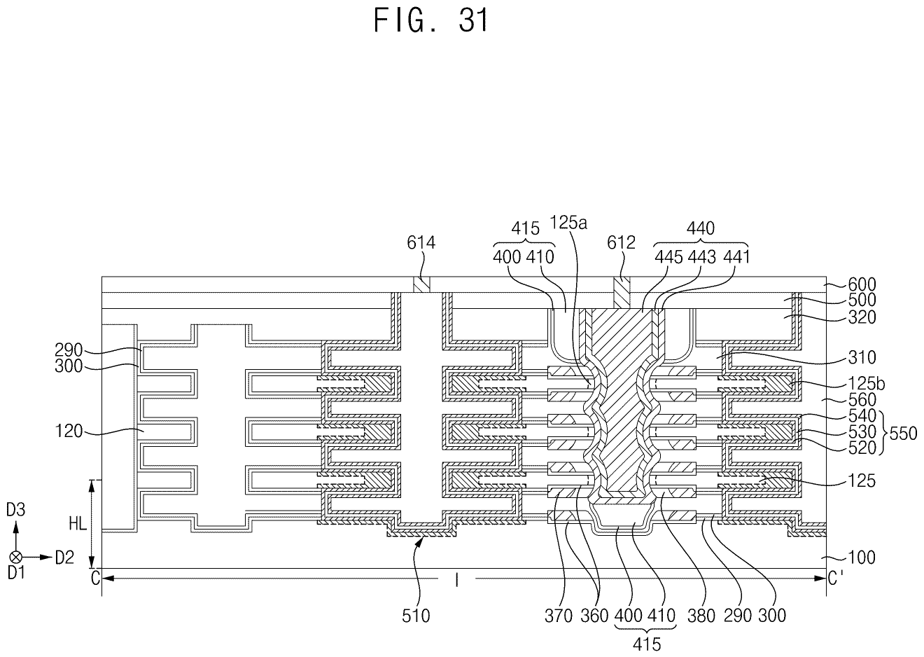

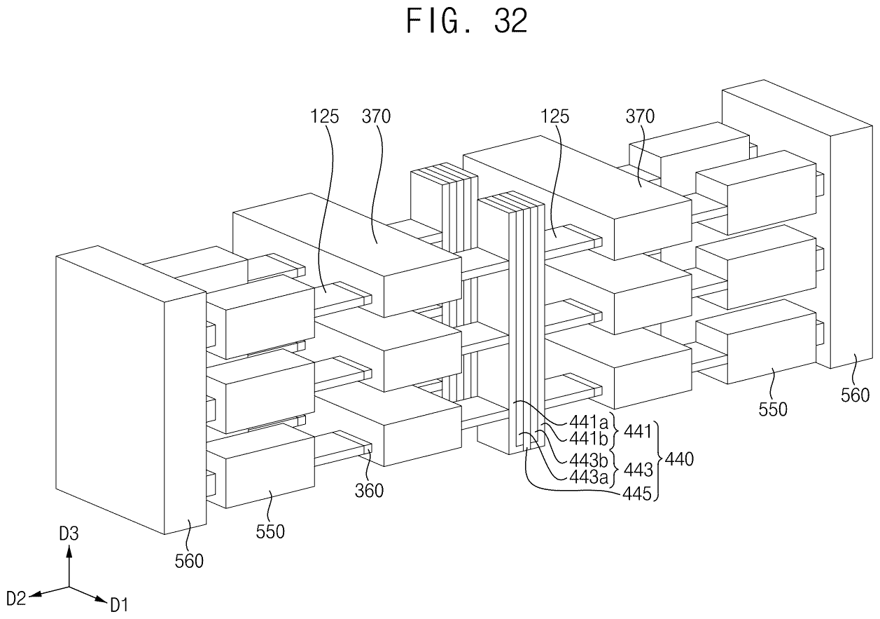

Referring to FIGS. 31 and 32, the capping layer 500, the second mask 320 and the third division structure may be partially removed by, e.g., a dry etching process to form eleventh openings 510 exposing the upper surface of the substrate 100.

In example embodiments, the eleventh openings 510 may expose sidewalls in the first direction D1 of the blocking structures 490.

For example, a wet etching process may be performed through the eleventh openings 510 to remove portions of the seventh division pattern 310 between the channels 125 adjacent to the eleventh openings 510 to form fifth gaps. During the wet etching process, portions of the first and second insulation patterns 290 and 300 on lower and upper surfaces and sidewalls of second end portions in the second direction D2 of the channels 125 may also be removed to expose the second end portions of the channels 125.

A gas phase doping process may be performed on the second end portions of the channels 125. Accordingly, terminal portions in the second direction D2 of the second end portions of the channels 125 may be formed to further include a second impurity, and may be referred to as second ohmic contacts 125b.

Alternatively, the second end portions of the channels 125 may be partially removed, and, for example, an epitaxial growth process may be performed using surfaces of the channels 125 as seeds. Accordingly, the second ohmic contacts 125b may also be formed to include a fourth semiconductor material doped with the second impurity. The fourth semiconductor material may include, for example, silicon, germanium, or silicon-germanium.

A first capacitor electrode layer, a dielectric layer and a second capacitor electrode layer may be sequentially stacked on inner walls of the fifth gaps, inner walls of the eleventh openings 510 and an upper surface of the capping layer 500, a plate electrode layer may be formed on the second capacitor electrode layer to fill the remaining portions of the fifth gaps and the eleventh openings 510, and a planarization process may be performed on the plate electrode layer, the second capacitor electrode layer, the dielectric layer and the first capacitor electrode layer until the upper surface of the capping layer 500 is exposed to form plate electrodes 560, second capacitor electrodes 540, dielectric patterns 530 and first capacitor electrodes 520, respectively (e.g., individually), in the fifth gaps and the eleventh openings 510.

The first capacitor electrodes 520, the dielectric patterns 530 and the second capacitor electrodes 540 may collectively form capacitors 550, and the capacitors 550 together with the plate electrodes 560 may collectively form capacitor structures. In example embodiments, a capacitor 550 may include portions of a first capacitor electrode 520, a dielectric pattern 530, and a second capacitor electrode 540 sequentially stacked a surface of the channel 125. In example embodiments, a capacitor structure may include a plate electrode 560 and the capacitors 550 disposed on opposite sidewalls in the second direction D2 of the plate electrode 560. The capacitor structure may extend in the first direction D1 on the first region I of the substrate 100.

Referring to FIGS. 1 to 5 again, a third insulating interlayer 600 may be formed on the capacitor structures and the capping layer 500, and first contact plugs 612 extending through the third insulating interlayer 600 and the capping layer 500 to contact upper surfaces of the bit line structures 440, second contact plug 614 extending through the third insulating interlayer 600 to contact upper surfaces of the capacitor structures, and third contact plugs 616 extending through the third insulating interlayer 600, the capping layer 500, the second mask 320 and the eighth division pattern 340 or the third insulating interlayer 600, the capping layer 500 and the second insulating interlayer 435 to contact upper surfaces of the conductive pads 430 may be formed.

By the above processes, manufacturing of the semiconductor device may be completed.

In the method of manufacturing the semiconductor device, the first ohmic contacts 125a may be formed by diffusion of the first impurity of the first conductive layer 441L into the channels 125. As compared to forming the first ohmic contacts 125a by using a gas phase doping process on the channels 125, concentration of the first impurity of the first ohmic contacts 125a may be more uniform along the third direction D3.

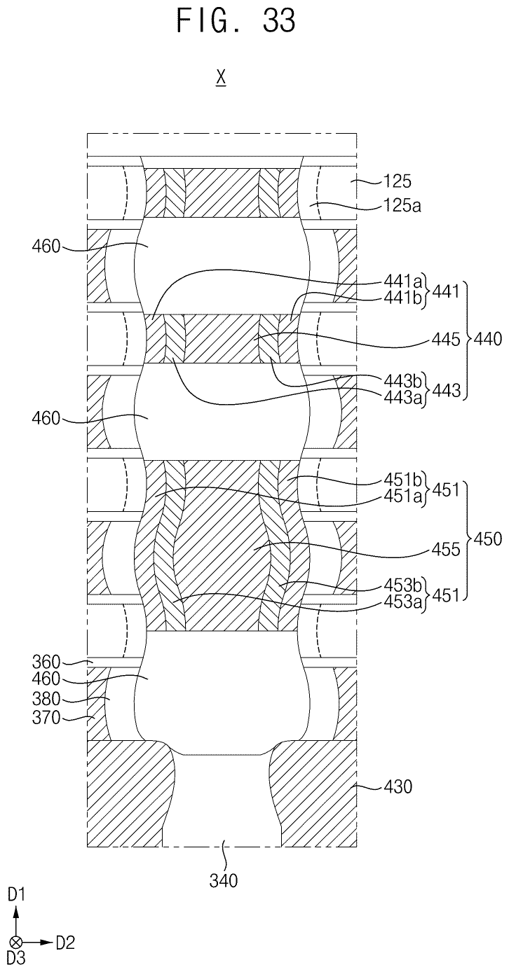

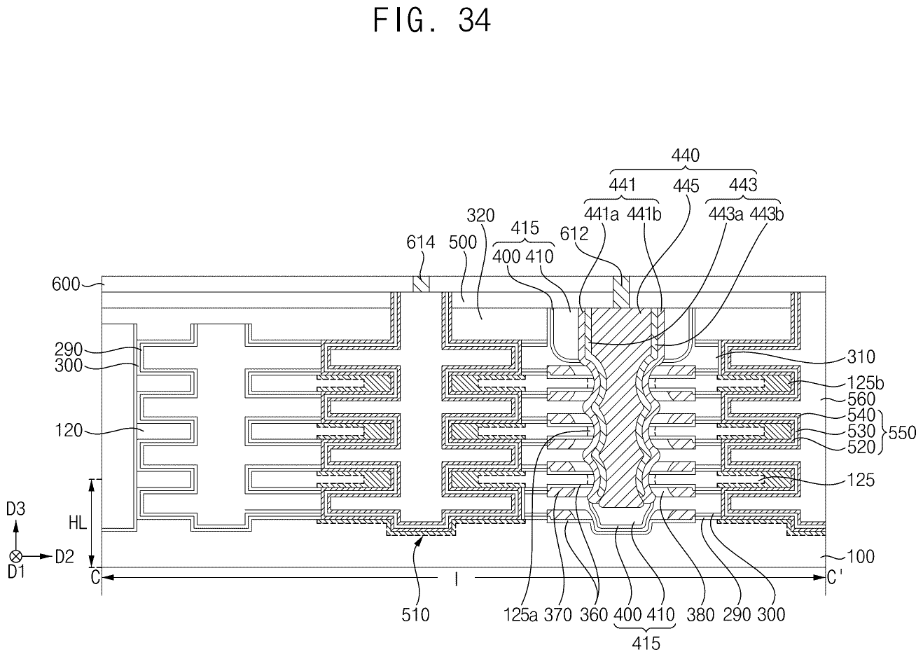

FIGS. 32 to 34 are a perspective view, a horizontal cross-sectional view and a vertical cross-sectional view illustrating a semiconductor device according to example embodiments, corresponding to FIGS. 1, 3 and 5, respectively (e.g., individually). The semiconductor device is substantially the same as or similar to those described with reference to FIGS. 1 to 5 except for the configuration of the bit line structures 440 and the dummy bit line structure 450, and thus, repeated explanations are omitted herein.

Referring to FIGS. 32 to 34, the first conductive pattern 441 and the second conductive pattern 443 included in the bit line structure 440 may include two first sub-conductive patterns 441a and 441b and two second sub-conductive patterns 443a and 443b, respectively (e.g., individually). For example, the bit line structure 440 may include one third conductive pattern 445, the two second sub-conductive patterns 443a and 443b covering opposite sidewalls in the second direction D2 of the one third conductive pattern 445, and the two first sub-conductive patterns 441a and 441b covering outer sidewalls in the second direction D2 of the two second sub-conductive patterns 443a and 443b.

In example embodiments, the third conductive pattern 445 may extend in the third direction D3. In example embodiments, the two second sub-conductive patterns 443a and 443b may cover upper portions of the opposite sidewalls in the second direction D2 of the third conductive pattern 445. In example embodiments, the first sub-conductive pattern 441a may cover the outer sidewall in the second direction D2 and a lower surface of the second sub-conductive pattern 443a, and a lower portion of a sidewall in the second direction D2 of the third conductive pattern 445, and the first sub-conductive pattern 441b may cover the outer sidewall in the second direction D2 and a lower surface of the second sub-conductive pattern 443b, and a lower portion of a sidewall in the second direction D2 of the third conductive pattern 445.

In example embodiments, a lower surface of the third conductive pattern 445 may be lower than lower surfaces of the two first sub-conductive patterns 441a and 441b.

The fourth conductive pattern 451 and the fifth conductive pattern 453 included in the dummy bit line structure 450 may include two fourth sub-conductive patterns 451a and 451b and two fifth sub-conductive patterns 453a and 453b, respectively (e.g., individually). For example, the dummy bit line structure 450 may include one sixth conductive pattern 455, the two fifth sub-conductive patterns 453a and 453b covering opposite sidewalls in the second direction D2 of the one sixth conductive pattern 455, and the two fourth sub-conductive patterns 451a and 451b covering outer sidewalls in the second direction D2 of the two fifth sub-conductive patterns 453a and 453b.

The two fourth sub-conductive patterns 451a and 451b, the two fifth sub-conductive patterns 453a and 453b, and the sixth conductive pattern 455 of the dummy bit line structure 450 may be substantially the same as or similar to the two first sub-conductive patterns 441a and 441b, the two second sub-conductive patterns 443a and 443b, and the third conductive pattern 445 of the bit line structure 440, respectively (e.g., individually), and thus, repeated explanations are omitted herein.

The bit line structures 440 and dummy bit line structure 450 of the semiconductor device described with reference to FIGS. 32 to 34 may be formed by forming the first and second conductive layers 441L and 443L in the first trench, removing portions of the first and second conductive layers 441L and 443L on the bottom of the first trench, forming the third conductive layer 445L to fill the remaining portion of the first trench, and performing the process described with reference to FIGS. 25 to 27.

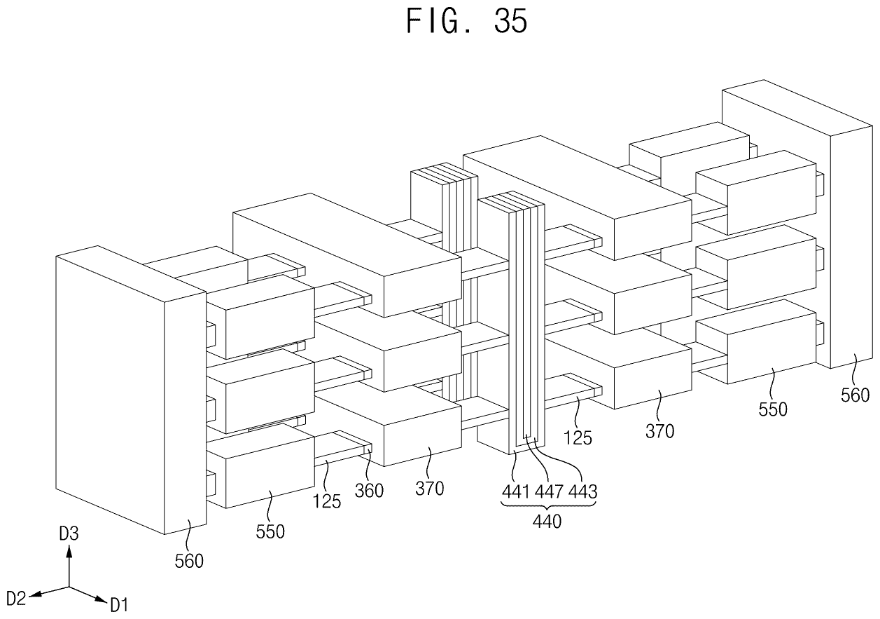

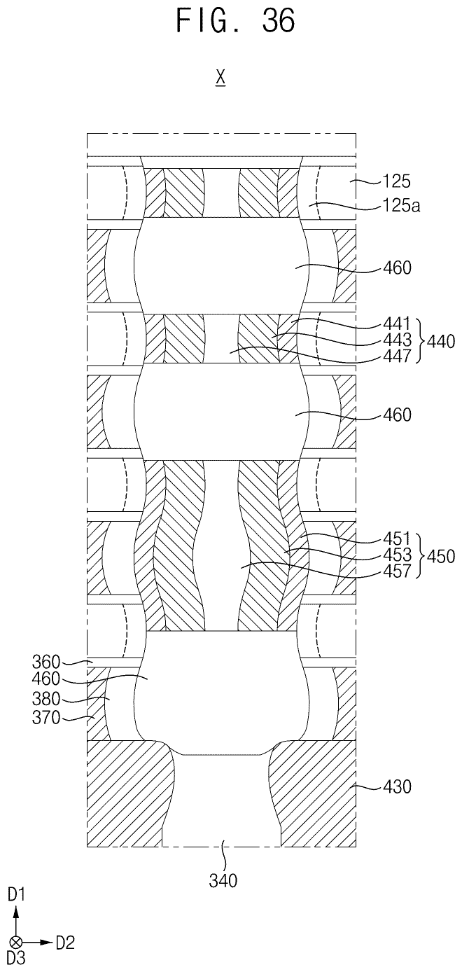

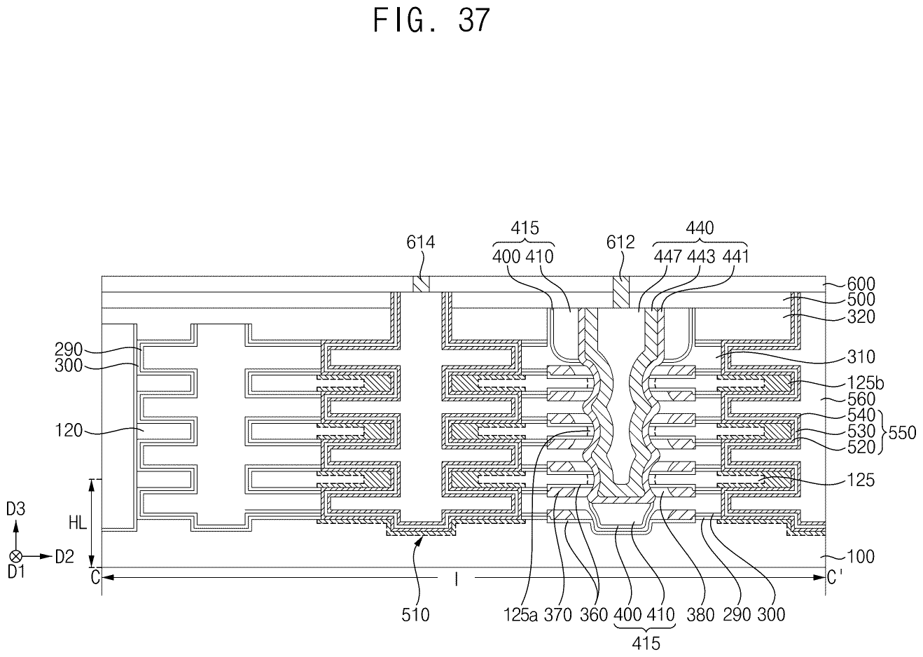

FIGS. 35 to 37 are a perspective view, a horizontal cross-sectional view and a vertical cross-sectional view illustrating a semiconductor device according to example embodiments, corresponding to FIGS. 1, 3 and 5, respectively (e.g., individually). The semiconductor device is substantially the same as or similar to those described with reference to FIGS. 1 to 5 except for the configuration of the bit line structures 440 and the dummy bit line structure 450, and thus, repeated explanations are omitted herein.

Referring to FIGS. 35 to 37, the bit line structure 440 may include a first filling pattern 447 instead of the third conductive patterns 445. In example embodiments, the bit line structure 440 may include the first filling pattern 447 and the second and first conductive patterns 443 and 441 sequentially stacked on opposite sidewalls in the second direction D2 and a lower surface of the first filling pattern 447. The first filling pattern 447 may include an oxide, for example, silicon oxide.

The dummy bit line structure 450 may include a second filling pattern 457 instead of the sixth conductive pattern 455. In example embodiments, the dummy bit line structure 450 may include the second filling pattern 457 and the fifth and fourth conductive patterns 453 and 451 sequentially stacked on opposite sidewalls in the second direction D2 and a lower surface of the second filling pattern 457. The second filling pattern 457 may include substantially the same material as the first filling pattern 447, for example, an oxide such as silicon oxide.

In example embodiments, the eleventh division patterns 460 may cover opposite sidewalls in the first direction D1 of the first and second filling patterns 447 and 457.

Although in FIGS. 32 to 34, the bit line structure 440 may include the first filling pattern 447 instead of the third conductive patterns 445, and the dummy bit line structure 450 may include the second filling pattern 457 instead of the sixth conductive pattern 455, the present invention is not limited thereto. For example, the bit line structure 440 may include the first filling pattern 447 instead of the second conductive pattern 443, and the dummy bit line structure 450 may include the second filling pattern 457 instead of the fifth conductive pattern 453.

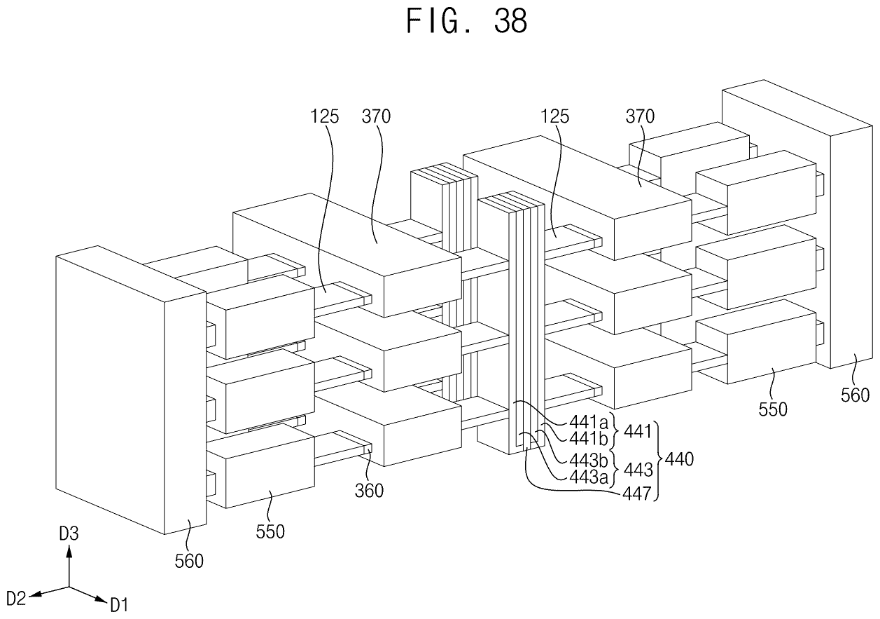

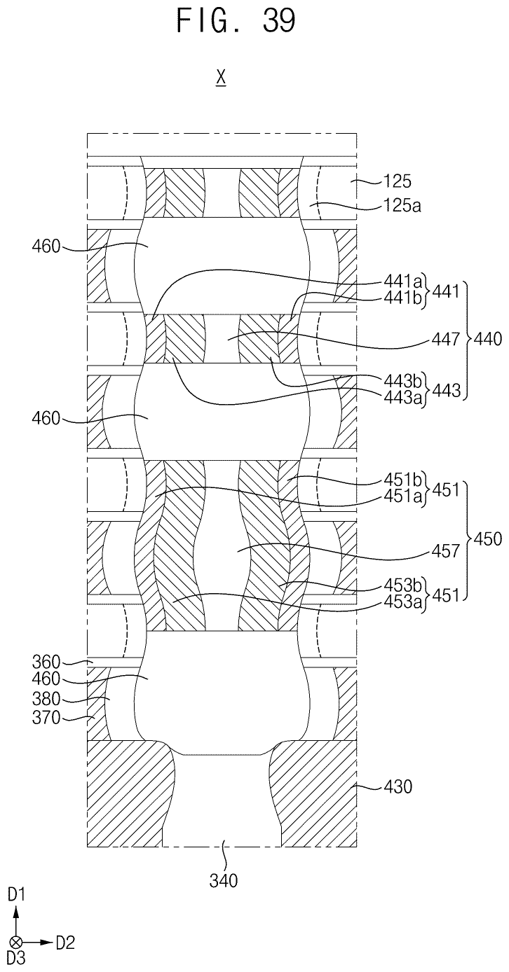

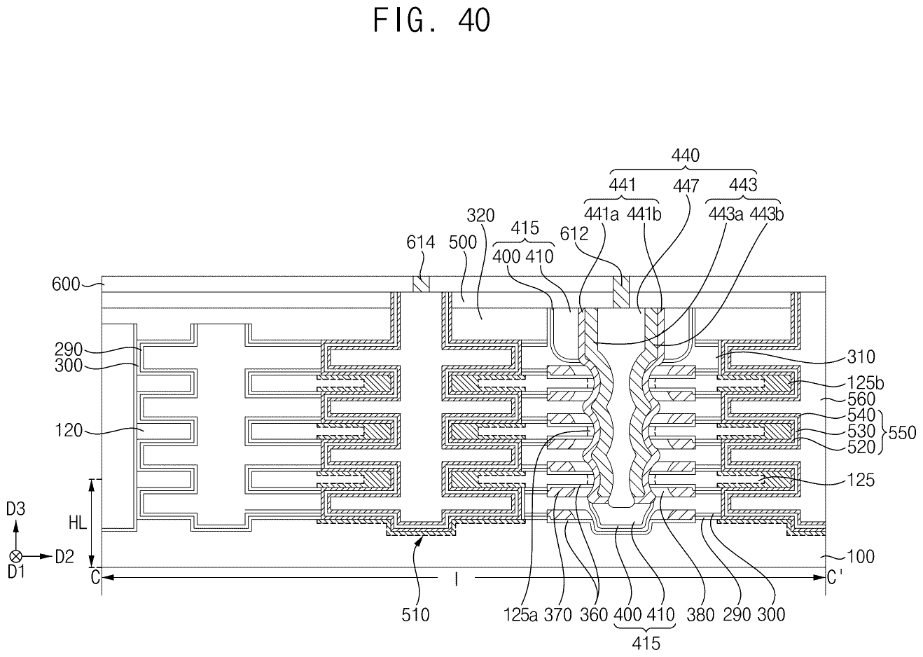

FIGS. 38 to 40 are a perspective view, a horizontal cross-sectional view and a vertical cross-sectional view illustrating a semiconductor device according to example embodiments, corresponding to FIGS. 35 to 37, respectively (e.g., individually). The semiconductor device is substantially the same as or similar to those described with reference to FIGS. 35 to 37 except for the configuration of the bit line structures 440 and the dummy bit line structure 450, and thus, repeated explanations are omitted herein.

Referring to FIGS. 38 to 40, the first conductive pattern 441 and the second conductive pattern 443 included in the bit line structures 440 may include two first sub-conductive patterns 441a and 441b and two second sub-conductive patterns 443a and 443b, respectively (e.g., individually). For example, the bit line structure 440 may include one first filling pattern 447, the two second sub-conductive patterns 443a and 443b covering opposite sidewalls in the second direction D2 of the one first filling pattern 447, and the two first sub-conductive patterns 441a and 441b covering outer sidewalls in the second direction D2 of the two second sub-conductive patterns 443a and 443b.

In example embodiments, the first filling pattern 447 may extend in the third direction D3. In example embodiments, the two second sub-conductive patterns 443a and 443b may cover upper portions of the opposite sidewalls in the second direction D2 of the first filling pattern 447. In example embodiments, the first sub-conductive pattern 441a may cover the outer sidewall in the second direction D2 and a lower surface of the second sub-conductive pattern 443a, and a lower portion of a sidewall in the second direction D2 of the first filling pattern 447, and the first sub-conductive pattern 441b may cover the outer sidewall in the second direction D2 and a lower surface of the second sub-conductive pattern 443b, and a lower portion of a sidewall in the second direction D2 of the first filling pattern 447.

In example embodiments, a lower surface of the first filling pattern 447 may be lower than lower surfaces of the two first sub-conductive patterns 441a and 441b.

The fourth conductive pattern 451 and the fifth conductive pattern 453 included in the dummy bit line structure 450 may include two fourth sub-conductive patterns 451a and 451b and two fifth sub-conductive patterns 453a and 453b, respectively (e.g., individually). For example, the dummy bit line structure 450 may include one second filling pattern 457, the two fifth sub-conductive patterns 453a and 453b covering opposite sidewalls in the second direction D2 of the one second filling pattern 457, and the two fourth sub-conductive patterns 451a and 451b covering outer sidewalls in the second direction D2 of the two fifth sub-conductive patterns 453a and 453b.

The two fourth sub-conductive patterns 451a and 451b, the two fifth sub-conductive patterns 453a and 453b, and the second filling pattern 457 of the dummy bit line structure 450 may be substantially the same as or similar to the two first sub-conductive patterns 441a and 441b, the two second sub-conductive patterns 443a and 443b, and the first filling pattern 447 of the bit line structure 440, respectively (e.g., individually), and thus, repeated explanations are omitted herein.

The bit line structures 440 and dummy bit line structure 450 of the semiconductor device described with reference to FIGS. 38 to 40, may be formed by forming the first and second conductive layers 441L and 443L in the first trench, removing portions of the first and second conductive layers 441L and 443L on the bottom of the first trench, forming a filling layer to fill the remaining portion of the first trench, and performing the process described with reference to FIGS. 25 to 27.

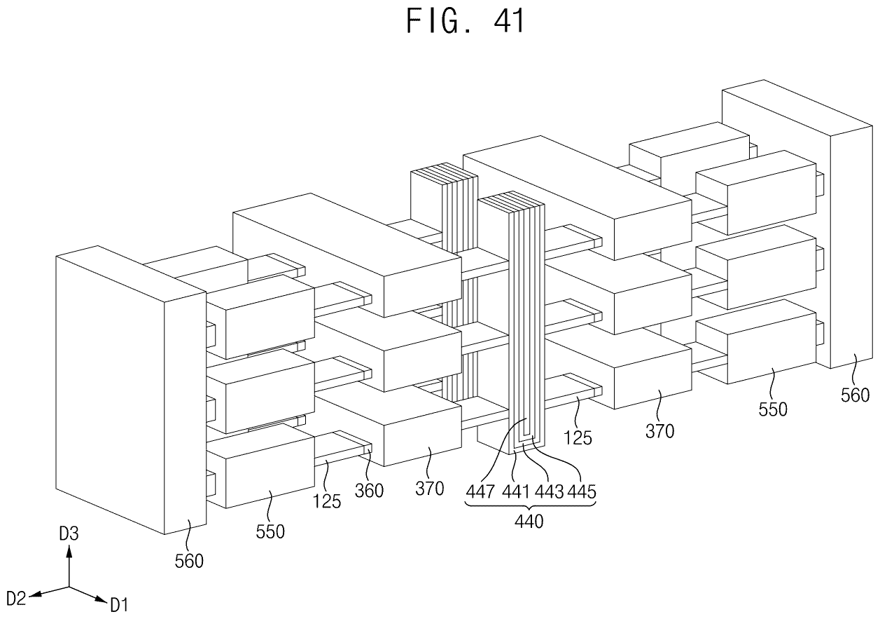

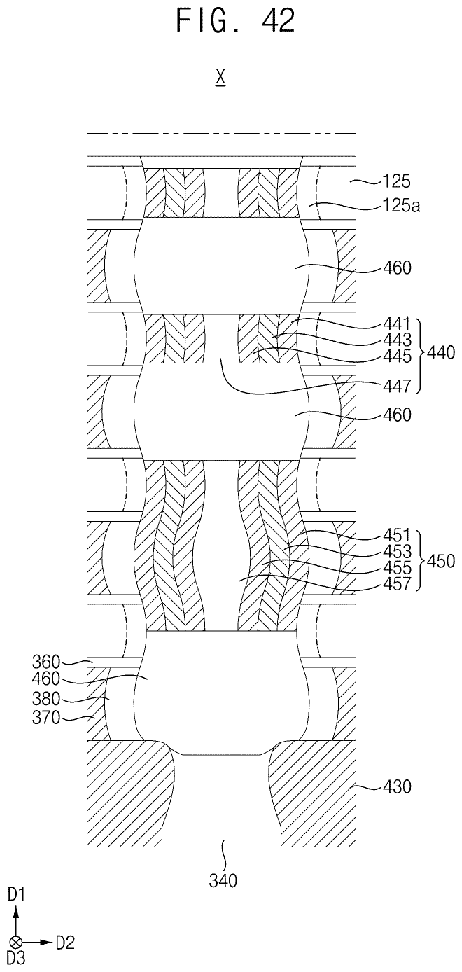

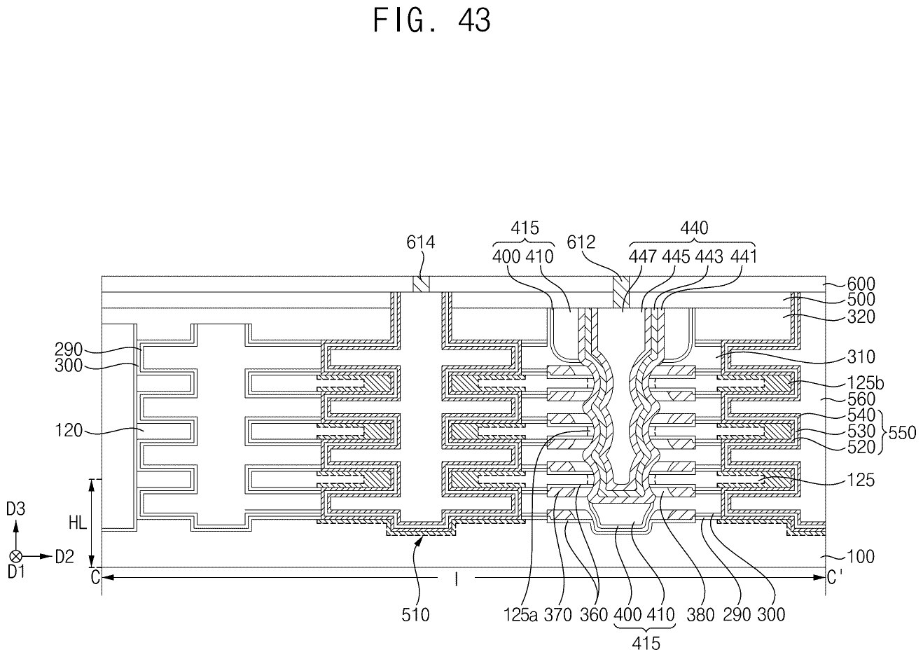

FIGS. 41 to 43 are a perspective view, a horizontal cross-sectional view and a vertical cross-sectional view illustrating a semiconductor device according to example embodiments, corresponding to FIGS. 1, 3 and 5, respectively (e.g., individually). The semiconductor device is substantially the same as or similar to those described with reference to FIGS. 1 to 5 except for the configuration of the bit line structures 440 and the dummy bit line structure 450, and thus, repeated explanations are omitted herein.

Referring to FIGS. 41 to 43, the bit line structure 440 may further include a first filling pattern 447. In example embodiments, the bit line structure 440 may include the first filling pattern 447 and the third, second, and first conductive patterns 445, 443 and 441 sequentially stacked on opposite sidewalls in the second direction D2 and a lower surface of the first filling pattern 447. The first filling pattern 447 may include an oxide, for example, silicon oxide.

The dummy bit line structure 450 may further include a second filling pattern 457. In example embodiments, the dummy bit line structure 450 may include the second filling pattern 457 and the sixth, fifth, and fourth conductive patterns 455, 453 and 451 sequentially stacked on opposite sidewalls in the second direction D2 and a lower surface of the second filling pattern 457. The second filling pattern 457 may include substantially the same material as the first filling pattern 447 an oxide, for example, silicon oxide.

In example embodiments, the eleventh division patterns 460 may cover opposite sidewalls in the first direction D1 of the first and second filling patterns 447 and 457.

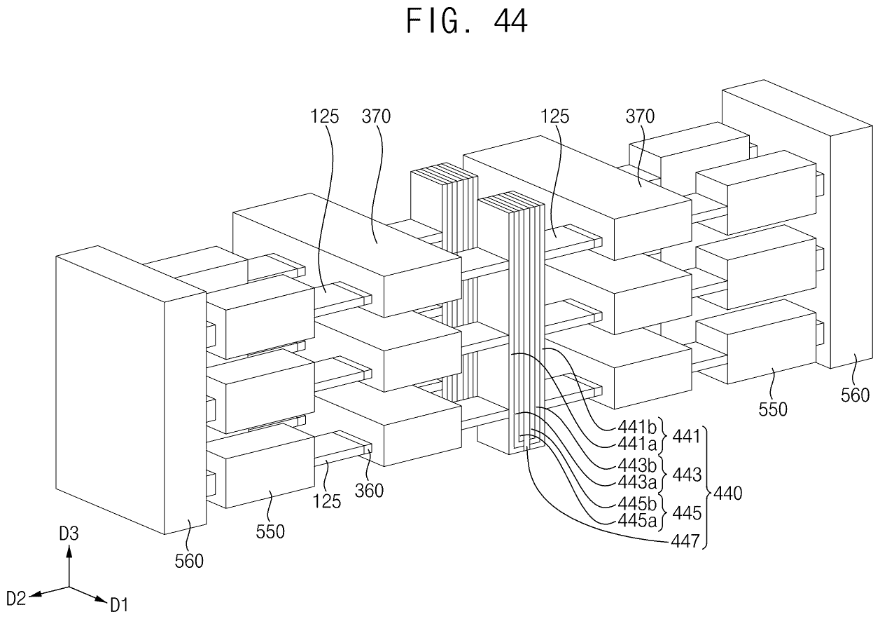

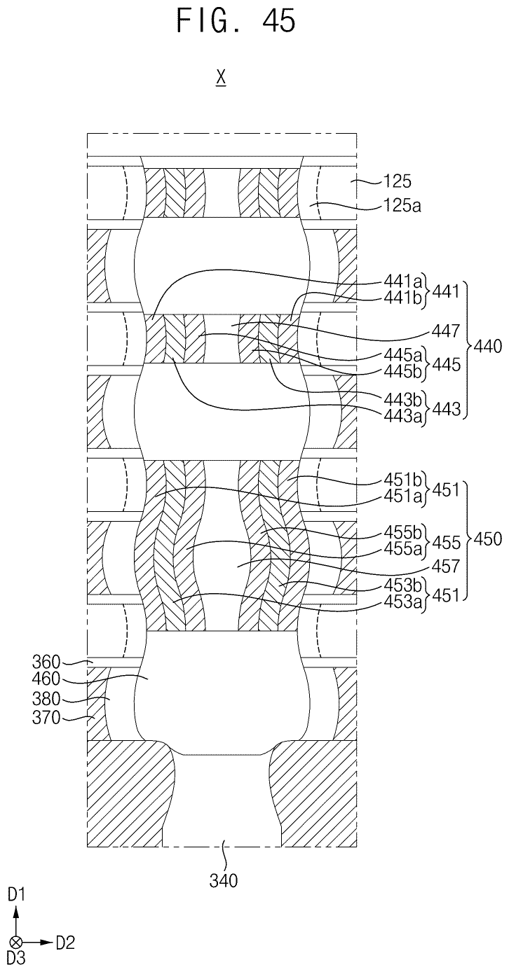

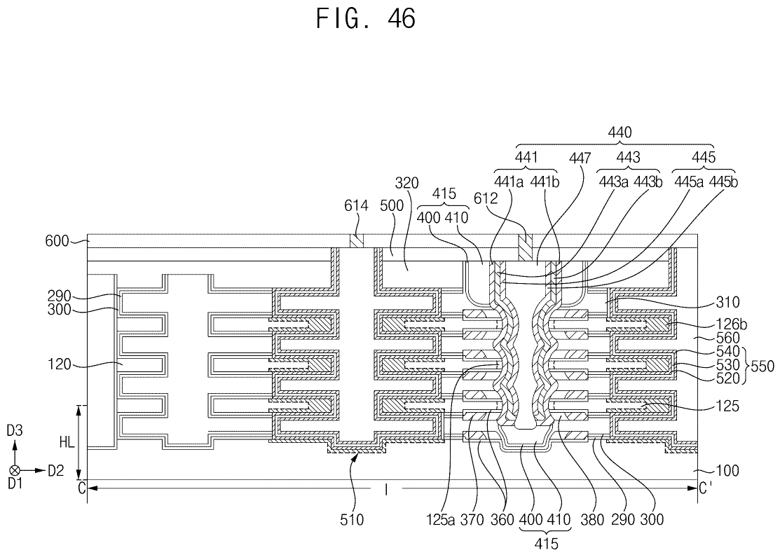

FIGS. 44 to 46 are a perspective view, a horizontal cross-sectional view and a vertical cross-sectional view illustrating a semiconductor device according to example embodiments, corresponding to FIGS. 41 to 43, respectively (e.g., individually). The semiconductor device is substantially the same as or similar to those described with reference to FIGS. 41 to 43 except for the configuration of the bit line structures 440 and the dummy bit line structure 450, and thus, repeated explanations are omitted herein.

Referring to FIGS. 44 to 46, the first conductive pattern 441, the second conductive pattern 443, and the third conductive pattern 445 included in the bit line structure 440 may include two first sub-conductive patterns 441a and 441b, two second sub-conductive patterns 443a and 443b, and two third sub-conductive patterns 445a and 445b, respectively (e.g., individually). For example, the bit line structure 440 may include one first filling pattern 447, the two third sub-conductive patterns 445a and 445b covering opposite sidewalls in the second direction D2 of the one first filling pattern 447, the two second sub-conductive patterns 443a and 443b covering outer sidewalls in the second direction D2 of the two third sub-conductive patterns 445a and 445b, and the two first sub-conductive patterns 441a and 441b covering outer sidewalls in the second direction D2 of the two second sub-conductive patterns 443a and 443b.

In example embodiments, the first filling pattern 447 may extend in the third direction D3. In example embodiments, the two third sub-conductive patterns 445a and 445b may cover upper portions of the opposite sidewalls in the second direction D2 of the first filling pattern 447. In example embodiments, the second sub-conductive pattern 443a may cover the outer sidewall in the second direction D2 and a lower surface of the third sub-conductive pattern 445a and a lower portion of a sidewall in the second direction D2 of the first filling pattern 447, and the second sub-conductive pattern 443b may cover the outer sidewall in the second direction D2 and a lower surface of the third sub-conductive pattern 445b and a lower portion of a sidewall in the second direction D2 of the first filling pattern 447. In example embodiments, the first sub-conductive pattern 441a may cover the outer sidewall in the second direction D2 and a lower surface of the second sub-conductive pattern 443a and a lower portion of a sidewall in the second direction D2 of the first filling pattern 447, and the first sub-conductive pattern 441b may cover the outer sidewall in the second direction D2 and a lower surface of the second sub-conductive pattern 443b and a lower portion of a sidewall in the second direction D2 of the first filling pattern 447.

In example embodiments, a lower surface of the first filling pattern 447 may be lower than lower surfaces of the two first sub-conductive patterns 441a and 441b.

The fourth conductive pattern 451, the fifth conductive pattern 453, and the sixth conductive pattern 455 included in the dummy bit line structure 450 may include two fourth sub-conductive patterns 451a and 451b, two fifth sub-conductive patterns 453a and 453b, and two sixth sub-conductive patterns 455a and 455b, respectively (e.g., individually). For example, the dummy bit line structure 450 may include one second filling pattern 457, the two sixth sub-conductive patterns 455a and 455b covering opposite sidewalls in the second direction D2 of the one second filling pattern 457, two fifth sub-conductive patterns 453a and 443b covering outer sidewalls in the second direction D2 of the two sixth sub-conductive patterns 455a and 455b, and two fourth sub-conductive patterns 451a and 451b covering outer sidewalls in the second direction D2 of the two fifth sub-conductive patterns 453a and 453b.

The two fourth sub-conductive patterns 451a and 451b, the two fifth sub-conductive patterns 453a and 453b, and the two sixth sub-conductive patterns 455a and 455b of the dummy bit line structure 450 may be substantially the same as or similar to the first sub-conductive patterns 441a and 441b, the two second sub-conductive patterns 443a and 443b, and the two third sub-conductive patterns 445a and 445b of the bit line structure 440, respectively (e.g., individually), and thus, repeated explanations are omitted herein.

The bit line structures 440 and the dummy bit line structure 450 of the semiconductor device described with reference to FIGS. 44 to 46 may be formed by forming the first to third conductive layers 441L, 443L and 445L in the first trench, removing portions of the first to third conductive layers 441L, 443L and 445L on the bottom of the first trench, forming a filling layer to fill the remaining portion of the first trench, and performing the process described with reference to FIGS. 25 to 27.

While the inventive concept has been shown and described with reference to exemplary embodiments thereof, it will be apparent to those of ordinary skill in the art that various modifications in form and details may be made thereto without departing from the spirit and scope of the inventive concept as set forth by the following claims.

What is claimed is:

1. A semiconductor device, comprising:
a substrate;
a bit line on the substrate, the bit line including a first conductive pattern, a second conductive pattern, and a third conductive pattern;
channels extending in a first horizontal direction that is parallel to an upper surface of the substrate;
gate electrodes extending in a second horizontal direction that is parallel to the upper surface of the substrate and crosses the first horizontal direction; and
capacitors on the substrate,
wherein:
the first conductive pattern extends in a vertical direction, the first conductive pattern includes a metal, and the first conductive pattern includes first opposite sidewalls facing away from each other in the first horizontal direction,
the second conductive pattern at least partially covers the first opposite sidewalls, the second conductive pattern includes a silicide, and the second conductive pattern includes second opposite sidewalls facing away from each other in the first horizontal direction,
the third conductive pattern at least partially covers the second opposite sidewalls, the third conductive pattern includes a first semiconductor material doped with first impurities, and the third conductive pattern includes third opposite sidewalls facing away from each other in the first horizontal direction,
the channels include a second semiconductor material, the channels are disposed spaced apart from each other along the vertical direction, each of the channels is formed on the third opposite sidewalls of a corresponding one of third conductive pattern, and each of the channels includes a first end portion and a second end portion that face away from each other in the first horizontal direction,
the gate electrodes extend in the second horizontal direction, and each of the gate electrodes at least partially surrounds the first end portion of a corresponding one of the channels, and
each of the capacitors is disposed on the second end portion of a corresponding one of the channels.

2. The semiconductor device of claim 1, wherein the first impurities are n-type impurities.

3. The semiconductor device of claim 1, further comprising conductive contacts, wherein
each of the conductive contacts is disposed between the third conductive pattern and the first end portion of a corresponding one of the channels, and
the conductive contacts include the second semiconductor material doped with the first impurities.

4. The semiconductor device of claim 1, further comprising isolation patterns, wherein
the bit line includes fourth opposite sidewalls facing away from each other in the second horizontal direction,
the isolation patterns are formed on the fourth opposite sidewalls,
the first conductive pattern includes fifth opposite sidewalls facing away from each other in the second horizontal direction,
the second conductive pattern includes sixth opposite sidewalls facing away from each other in the second horizontal direction,
the third conductive pattern includes seventh opposite sidewalls facing away from each other in the second horizontal direction, and
the isolation patterns cover the fifth opposite sidewalls, the sixth opposite sidewalls, and the seventh opposite sidewalls.

5. The semiconductor device of claim 1, wherein the second conductive pattern covers a lower surface of the first conductive pattern, and the third conductive pattern covers a lower surface of the second conductive pattern.

6. The semiconductor device of claim 1, wherein:
the second conductive pattern includes two second sub-conductive patterns,
the two second sub-conductive patterns are spaced from each other,
the two second sub-conductive patterns include fourth sidewalls,
the third conductive pattern includes two third sub-conductive patterns,
the two third sub-conductive patterns are spaced from each other,
the two second sub-conductive patterns cover upper portions of the first opposite sidewalls of the first conductive pattern, and
the two third sub-conductive patterns cover the fourth sidewalls and lower surfaces of the two second sub-conductive patterns, and lower portions of the first opposite sidewalls of the first conductive pattern.

7. The semiconductor device of claim 6, wherein a lower surface of the first conductive pattern is lower than lower surfaces of the two third sub-conductive patterns.

8. The semiconductor device of claim 1, wherein, with respect to a cross-section of the bit line extending in the first and second horizontal directions and extending through a first channel among the channels:
a width in the first horizontal direction of the bit line is minimum at a center of the bit line in the second horizontal direction, and
the width of the bit line in the first horizontal direction is maximum at least one of opposite end portions of the bit line in the second horizontal direction.

9. The semiconductor device of claim 1, further comprising an isolation pattern between the gate electrodes, wherein, with respect to a cross-section of the bit line extending in the first horizontal direction and the vertical direction, widths of the bit line in the first horizontal direction at vertical levels corresponding to the vertical levels of the channels are each less than each of the widths of the bit line in the first horizontal direction at vertical levels corresponding to the vertical levels of the isolation pattern.

10. A semiconductor device comprising:
a substrate;
a bit line on the substrate, the bit line including a filling pattern, a first conductive pattern, and a second conductive pattern;
a channel extending in a first horizontal direction that is parallel to an upper surface of the substrate;
gate electrodes extending in a second horizontal direction that is parallel to the upper surface of the substrate and crosses the first horizontal direction;
a gate electrode extending in the second horizontal direction; and
capacitors on the substrate,
wherein:
the bit line includes a first sidewall facing along the first horizontal direction,
the filling pattern extends in a vertical direction,
the filling pattern includes second opposite sidewalls facing away from each other in the first horizontal direction,
the first conductive pattern at least partially covers the second opposite sidewalls of the filling pattern,
the first conductive pattern includes a silicide,
the first conductive pattern includes third opposite sidewalls facing away from each other in the first horizontal direction,
the second conductive pattern at least partially covers the third opposite sidewalls,
the second conductive pattern includes a first semiconductor material doped with first impurities,
the channel extends in the first horizontal direction from the first sidewall the bit line,
the channel includes first and second end portions facing away from each other in the first horizontal direction,
the first end portion includes fourth opposite sidewalls facing away from each other in the second horizontal direction,
the second horizontal direction is parallel to the upper surface of the substrate and crosses the first horizontal direction,
the gate electrode at least partially covers upper and lower surfaces and the fourth opposite sidewalls of the first end portion of the channel,
the capacitor at least partially covers the second end portion of the channel, and
a portion of the first end portion of the channel adjacent to the second conductive pattern includes the first impurities.

11. The semiconductor device of claim 10, wherein the first impurities are n-type impurities.

12. The semiconductor device of claim 10, further comprising isolation patterns, wherein
the bit line includes fifth opposite sidewalls facing away from each other in the second horizontal direction,
the isolation patterns are formed on the fifth opposite sidewalls of the bit line,
the filling pattern includes sixth opposite sidewalls facing away from each other in the second horizontal direction,
the first conductive pattern includes seventh opposite sidewalls facing away from each other in the second horizontal direction,
the second conductive pattern includes eighth opposite sidewalls facing away from each other in the second horizontal direction, and
the isolation patterns cover the sixth opposite sidewalls of the filling pattern, the seventh opposite sidewalls of the first conductive pattern, and the eighth opposite sidewalls of the second conductive pattern.

13. The semiconductor device of claim 10, wherein:
the first conductive pattern covers the second opposite sidewalls and a lower surface of the filling pattern, and
the second conductive pattern covers the third opposite sidewalls and a lower surface of the first conductive pattern.

14. The semiconductor device of claim 10, wherein:
the first conductive pattern includes two first sub-conductive patterns,
the second conductive pattern includes two second sub-conductive patterns,
the two first sub-conductive patterns cover upper portions of the third opposite sidewalls of the filling pattern,
the two first sub-conductive patterns include fifth opposite sidewalls facing away from each other in the first horizontal direction,
the two second sub-conductive patterns cover the fifth opposite sidewalls and lower surfaces of the two first sub-conductive patterns, and
the two second sub-conductive patterns cover lower portions of the third opposite sidewalls of the filling pattern.

15. The semiconductor device of claim 14, wherein a lower surface of the filling pattern is lower than lower surfaces of the two second sub-conductive patterns.

16. A semiconductor device comprising:
a substrate;
bit lines on the substrate and spaced apart from each other in a first horizontal direction parallel to an upper surface of the substrate, each of the bit lines including a filling pattern, a first conductive pattern, a second conductive pattern and a third conductive pattern;
isolation patterns between neighboring ones of the bit lines in the first horizontal direction, the isolation patterns extending in a vertical direction;
channels extending in a second horizontal direction that is parallel to the upper surface of the substrate and crosses the first horizontal direction;
gate electrodes extending in the first horizontal direction; and
capacitors on the substrate,
wherein:
the filling patterns extend in the vertical direction,
each of the filling patterns includes first opposite sidewalls facing away from each other in the second horizontal direction,
each of the filling patterns further includes second opposite sidewalls facing away from each other in the first horizontal direction,
each of the first conductive patterns covers the first opposite sidewalls of a corresponding one of the filling patterns,
the first conductive patterns include a metal,
each of the first conductive patterns includes third opposite sidewalls facing away from each other in the second horizontal direction,
each of the first conductive patterns further includes fourth opposite sidewalls facing away from each other in the first horizontal direction,
each of the second conductive patterns at least partially covers the third opposite sidewalls of a corresponding one of the first conductive patterns,
each of the second conductive patterns includes a silicide,
each of the second conductive patterns includes fifth opposite sidewalls facing away from each other in the second horizontal direction,
each of the second conductive patterns further includes sixth opposite sidewalls facing away from each other in the second horizontal direction,
each of the third conductive patterns at least partially covers the fifth opposite sidewalls of a corresponding one of the second conductive patterns,
the third conductive patterns include a semiconductor material doped with first impurities,
each of the third conductive patterns includes seventh opposite sidewalls facing away from each other in the second horizontal direction,
each of the third conductive patterns further includes eighth opposite sidewalls facing away from each other in the second horizontal direction,
each of the isolation patterns covers the second opposite sidewalls of a corresponding one of the filling patterns, the third opposite sidewalls of a corresponding one of the first conductive patterns, the sixth opposite sidewalls of a corresponding one of the second conductive patterns, and the eighth opposite sidewalls of a corresponding one of the third conductive patterns,
each of the channels is disposed on the seventh opposite sidewalls of a corresponding one of the third conductive patterns,
each of the channels extends in the second horizontal direction,
the channels are spaced apart from each other along the vertical direction,
each of the gate electrodes at least partially surrounds a first end portion in the second horizontal direction of a corresponding one of the channels, and
each of the capacitors at least partially covers a second end portion in the second horizontal direction of a corresponding one of the channels.

17. The semiconductor device of claim 16, wherein the first impurities are n-type impurities.

18. The semiconductor device of claim 16, further comprising conductive contacts, each of the conductive contacts disposed between a corresponding one of the third conductive patterns and a corresponding one of the first end portions of the channels, the conductive contacts including a semiconductor material doped with the first impurities.

19. The semiconductor device of claim 16, wherein each of the second conductive patterns covers lower surfaces of a corresponding one of the first conductive patterns, and each of the third conductive patterns covers lower surfaces of a corresponding one of the second conductive patterns.

20. The semiconductor device of claim 16, wherein lower surfaces of the filling patterns are lower than lower surfaces of the third conductive patterns.
